(19) United States
(12) Patent Application Publication
(10) Pub. No.: US 2025/0257457 A1
(43) Pub. Date: Aug. 14, 2025

(54) ELECTRON-ENHANCED METAL OXIDE ATOMIC LAYER DEPOSITION

(71) Applicants: SAMSUNG ELECTRONICS CO., LTD., Suwon-si (KR); THE REGENTS OF THE UNIVERSITY OF COLORADO, A BODY CORPORATE, Denver, CO (US)

(72) Inventors: Steven GEORGE, Boulder, CO (US); Jonas GERTSCH, Eden Prairie, MN (US); Zachary SOBELL, Boulder, CO (US); Harsono SIMKA, Saratoga, CA (US)

(73) Assignees: SAMSUNG ELECTRONICS CO., LTD., Suwon-si (KR); THE REGENTS OF THE UNIVERSITY OF COLORADO, A BODY CORPORATE, Denver, CO (US)

(21) Appl. No.: 18/746,960

(22) Filed: Jun. 18, 2024

Related U.S. Application Data
(60) Provisional application No. 63/552,927, filed on Feb. 13, 2024.

(51) Int. Cl. C23C 16/455; C23C 16/40; H01L 21/02

(52) U.S. Cl. CPC C23C 16/45536; C23C 16/402; H01L 21/02164; H01L 21/02181; H01L 21/02186; H01L 21/02189; H01L 21/02211; H01L 21/0228

(57) ABSTRACT

A method for forming a metal oxide insulating film includes conducting electron-enhanced atomic layer deposition with at least one metal-containing precursor gas and at least one oxygen-containing precursor gas as reactants to deposit a metal oxide insulating film on a substrate. The metal oxide can be SiO₂, TiO₂, HfO₂, or ZrO₂. A particular method for forming a SiO₂ film includes conducting electron-enhanced atomic layer deposition with at least one silicon-containing precursor gas and at least one oxygen-containing precursor gas as reactants to deposit a SiO₂ film on a substrate, wherein the electron-enhanced atomic layer deposition is conducted at a temperature of less than 300° C. A SiO₂ film produced by the method can be a blanket film or a patterned structure.

### CROSS-REFERENCE TO RELATED APPLICATION

This application is based on and claims priority from U.S. Provisional Application No. 63/552,927 filed on Feb. 13, 2024 in the U.S. Patent and Trademark Office, the disclosure of which is incorporated herein by reference in its entirety.

### BACKGROUND

### 1. Field

Methods according to embodiments relate to methods for forming a metal oxide insulating film involving conducting electron-enhanced atomic layer deposition with at least one metal-containing precursor gas and at least one oxygen-containing precursor gas as reactants, and films according to embodiments are films produced by the methods.

### 2. Description of the Related Art

Electrons can provide a non-thermal means to enhance thin film growth at low temperature. The interaction between electrons and surface species can lead to the desorption of the surface species via electron stimulated desorption (ESD). This ESD can create reactive sites on the surface that facilitate adsorption of reactants and thin film growth. Electrons can also collide with gas phase species and induce dissociation. This dissociation creates radical species that can react with the surface and promote thin film growth.

Most of the work on electron-enhanced growth has concentrated on focused electron beams. The field of focused electron beam induced deposition (FEBID) has developed direct write methods for patterned deposition and nanostructure fabrication. In contrast, there are very few reports of using broad electron beams for thin film growth over large surface areas. Although plasma atomic layer deposition (ALD) is widely employed for thin film growth, there have been few investigations of electron-enhanced ALD (EE-ALD).

EE-ALD has been demonstrated for GaN, Si, BN, and Co film growth. GaN is a binary compound and GaN EE-ALD employed Ga(CH₃)₃, NH₃, and electrons as the reactants. Si is a single element, and Si EE-ALD used only Si₂H₆ and electrons as the reactants. Although BN is a binary compound, BN EE-ALD utilized the single-source precursor borazine (B₃N₃H₆) and electrons as the reactants. Co is a single element film and Co EE-ALD employed CoNO(CO)₃ and electrons as the reactants. These films were all grown at room temperature using electrons with an energy of 75-175 eV from an electron gun. The electron gun could only provide limited electron currents of ≤100 μA and required low pressures of ≤10⁻⁷ Torr.

New electron sources have been developed for EE-ALD using a hollow cathode plasma electron source (HC-PES). The HC-PES can deliver much higher electron currents of >100 mA and can operate at higher chamber pressures of ˜5 mTorr. Co EE-ALD was recently demonstrated using the HC-PES with shorter cycle times and larger growth areas compared with the earlier Co EE-ALD studies based on the electron gun. In addition, TiN EE-ALD was recently accomplished using tetrakis(dimethylamido) titanium (TDMAT) and electron exposures in a continuous NH₃ reactive background gas. The NH₃ background gas at ˜1 mTorr greatly improved the purity of the TiN EE-ALD film presumably by providing ·NH₂ and ·H radicals from electron impact dissociation of gas phase NH₃.

Silicon dioxide (SiO₂) is one of the most common oxides. SiO₂ is an important dielectric material in semiconductor devices. SiO₂ is also used extensively as a transparent barrier coating material and as an anti-reflective optical coating. SiO₂ is a widely used support for metals in heterogeneous catalysis. In addition, SiO₂ is a common substrate for the deposition of many other thin films. Various ALD and chemical vapor deposition (CVD) methods have been developed previously for gas-phase SiO₂ deposition at low temperature.

Thermal SiO₂ ALD has been demonstrated at high temperatures of 330-530° C. using SiCl₄ and H₂O as the precursors. Other studies have demonstrated thermal SiO₂ ALD at >450° C. using tris(dimethylamino)silane and H₂O₂ as the precursors. Catalyzed SiO₂ ALD using various amines as the catalyst can reduce the SiO₂ deposition temperature to 25° C. Plasma SiO₂ ALD using precursors such as bis(diethylamino)silane together with O₂ plasma can also lower the deposition temperature to 25-50° C. These plasma SiO₂ ALD films may have high hydrogen content. In contrast, as discussed below, SiO₂ EE-ALD is performed in this disclosure at 35° C. without the need for plasma activation, halide precursors, or catalysts.

Chemical vapor deposition (CVD) methods can also deposit SiO₂ at low temperature. Catalyzed SiO₂ CVD has been demonstrated at 40-60° C. using SiCl₄ and H₂O with an NH₃ catalyst. Plasma-enhanced CVD has also been performed at 40° C. using a tetraethyl orthosilicate and O₂ plasma discharge. Other demonstrations of plasma SiO₂ CVD have been reported at temperatures from 100-350° C. Electron-assisted SiO₂ CVD has also been achieved at temperatures as low as 150° C. when the electrons only interacted with gas phase reactants. Lower temperatures down to room temperature were possible when the electrons could also interact with the substrate.

However, there remains a need for an improved method for forming a metal oxide insulating film such as a SiO₂ film, as well as a need for a metal oxide insulating film such as a SiO₂ film formed by such a method.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

It is an object of the present disclosure to provide an improved method for forming a metal oxide film, as well as to provide a metal oxide film formed by such a method.

To meet the above and other objects, the present disclosure provides a number of embodiments, including the following.

A first embodiment of the present disclosure includes a metal oxide insulating film, comprising
conducting electron-enhanced atomic layer deposition with at least one metal-containing precursor gas and at least one oxygen-containing precursor gas as reactants to deposit a metal oxide insulating film on a substrate.

A second embodiment of the present disclosure includes a method of the first embodiment, wherein the metal oxide is selected from the group consisting of SiO₂, TiO₂, HfO₂, and ZrO₂.

A third embodiment of the present disclosure includes a method of the first embodiment, wherein the metal oxide insulating film is a SiO₂ film and the method comprises: conducting electron-enhanced atomic layer deposition with at least one silicon-containing precursor gas and at least one oxygen-containing precursor gas as reactants to deposit a SiO₂ film on a substrate, wherein the electron-enhanced atomic layer deposition is conducted at a temperature of less than 300° C.

A fourth embodiment of the present disclosure includes a method of the third embodiment, wherein the at least one silicon-containing precursor gas comprises Si₂H₆.

A fifth embodiment of the present disclosure includes a method of the third embodiment, wherein the at least one silicon-containing precursor gas comprises SiH₄.

A sixth embodiment of the present disclosure includes a method of the third embodiment, wherein the at least one oxygen-containing precursor gas comprises H₂O.

A seventh embodiment of the present disclosure includes a method of the third embodiment, wherein the at least one oxygen-containing precursor gas comprises O₃.

An eighth embodiment of the present disclosure includes a method of the third embodiment, wherein the at least one oxygen-containing precursor gas comprises O₂.

A ninth embodiment of the present disclosure includes a method of the third embodiment, wherein the electron-enhanced atomic layer deposition is conducted with electrons produced by a hollow cathode plasma electron source.

A tenth embodiment of the present disclosure includes a method of the third embodiment, wherein the electron-enhanced atomic layer deposition is conducted at a temperature of less than 250° C.

An eleventh embodiment of the present disclosure includes a method of the third embodiment, wherein the electron-enhanced atomic layer deposition is conducted at a temperature of less than 200° C.

A twelfth embodiment of the present disclosure includes a method of the third embodiment, wherein the electron-enhanced atomic layer deposition is conducted at a temperature of less than 100° C.

A thirteenth embodiment of the present disclosure includes a method of the third embodiment, wherein the electron-enhanced atomic layer deposition is conducted at a temperature of from 15° C. to less than 100° C.

A fourteenth embodiment of the present disclosure includes a method of the third embodiment, comprising pulsing electrons sequentially with the at least one silicon-containing precursor gas and the at least one oxygen-containing precursor gas.

A fifteenth embodiment of the present disclosure includes a method of the third embodiment, comprising co-dosing electrons with the at least one oxygen-containing precursor gas, followed by sequential dosing of the at least one silicon-containing precursor gas.

A sixteenth embodiment of the present disclosure includes a method of the first embodiment, wherein the precursor gases are not subjected to thermal or plasma activation.

A seventeenth embodiment of the present disclosure includes a metal oxide insulating film produced by the method of the first embodiment.

An eighteenth embodiment of the present disclosure includes a SiO₂ film produced by the method of the third embodiment.

A nineteenth embodiment of the present disclosure includes a SiO₂ film of the eighteenth embodiment, wherein the SiO₂ film is a blanket film.

A twentieth embodiment of the present disclosure includes a SiO₂ film of the eighteenth embodiment, wherein the SiO₂ film is a patterned structure.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Example embodiments of the present disclosure will be more clearly understood from the following detailed description taken in conjunction with the accompanying drawings in which:

FIG. 1 shows a V-shaped reactor with a hollow cathode plasma electron source above the sample at the center of the V, wherein spectroscopic ellipsometry connects to the two ends of the V, and pumping ports to either a mechanical pump or turbomolecular pump connect through the 4-way cross.

FIG. 2(a) is a graph showing a processing sequence for SiO₂ EE-ALD based on sequential electron, O₃, and Si₂H₆ exposures, wherein N₂ flow is continuous except during electron exposures, and FIG. 2(b) is a graph showing SiO₂ EE-ALD based on co-dosing electron and O₃ exposures in sequence with Si₂H₆ exposure, wherein N₂ flow is continuous except during electron exposures.

FIG. 3 is a graph showing SiO₂ thickness versus time during SiO₂ EE-ALD based on sequential electron, O₃, and Si₂H₆ exposures, wherein SiO₂ growth rate is 0.89 Å/cycle over 500 ALD cycles.

FIG. 4 is a graph showing SiO₂ EE-ALD growth rate versus exposure time based on sequential electron, O₃, and Si₂H₆ exposures for the electron or Si₂H₆ exposure, wherein Si₂H₆ exposure was fixed at 1 s when varying electron exposure, and wherein electron exposure was fixed at 3 s when varying Si₂H₆ exposure.

FIG. 5 is a graph showing SiO₂ EE-ALD growth rate versus bias grid voltage on the hollow cathode plasma electron source, wherein SiO₂ EE-ALD was based on sequential electron, O₃, and Si₂H₆ exposures.

FIG. 6 is a graph showing SiO₂ thickness versus time during SiO₂ EE-ALD based on sequential electron, H₂O, and Si₂H₆ exposures, wherein SiO₂ growth rate is 0.88 Å/cycle over 180 ALD cycles.

FIG. 7 is a graph showing SiO₂ thickness versus time during SiO₂ EE-ALD based on sequential electron, Si₂H₆, and O₃ exposures, wherein SiO₂ growth rate is 0.68 Å/cycle over 240 ALD cycles.

FIG. 8 is a graph showing SiO₂ thickness versus time during SiO₂ EE-ALD based on co-dosing electron and O₃ exposures in sequence with Si₂H₆ exposures, wherein SiO₂ growth rate is 0.73 Å/cycle over 195 ALD cycles.

FIG. 9 is a graph showing SiO₂ EE-ALD growth rate versus exposure time based on co-dosing electron and O₃ exposures in sequence with Si₂H₆ exposures, wherein Si₂H₆ exposure was fixed at 1 s when co-dosing electron and O₃ exposures, and wherein Co-dosing O₃/electron exposure was fixed at 3 s when varying Si₂H₆ exposure.

FIG. 10 is a graph showing the etch rate of SiO₂ EE-ALD films in dilute buffered oxide etch solution for all SiO₂ EE-ALD process conditions, wherein SiO₂ thermal oxide (TO) is also included for comparison, sequence (s) or co-dosing (c) conditions are indicated and electron exposures are not designated explicitly, and Si₂H₆ exposures are also not designated explicitly for the co-dosing conditions.

FIG. 11 is an illustration of electron current on an insulator during EE-ALD.

FIG. 12 is an illustration of electron current on a conductor during EE-ALD.

FIG. 13 is a photograph of an EE-ALD reactor.

FIG. 14 is an illustration of hollow cathode operation.

FIG. 15 is an illustration of secondary electron yield.

FIG. 16 is a graph showing thickness vs. time for SiO₂ EE-ALD with e⁻ and O₃ sequential dosing.

FIG. 17 sets forth a graph showing growth per cycle vs. exposure time and a graph showing growth rate vs. bias grid for SiO₂ EE-ALD with e and O₃ sequential dosing.

FIG. 18 is a graph showing leakage current of EE-ALD SiO₂ films.

FIG. 19 is a graph showing ATR_FTIR spectroscopy results.

FIG. 20 is a graph showing estimated e⁻ dose for EE-ALD SiO₂ deposition.

FIG. 21 is a list of key points given SEY>1.

FIG. 22 is an illustration for stage current comparison.

FIG. 23 is a graph showing stage current comparison.

FIG. 24 is an illustration with a summary for a SiO₂ EE-ALD process.

FIG. 25(a) is a comparison between Ion Energy Distribution (IED) versus ion energy (here assumed to be electron energy) for 200 V and 300 V bias grid voltages, and FIG. 25(b) is a comparison between Ion Energy Distribution (IED) versus ion energy (here assumed to be electron energy) varying collimating coil currents.

FIG. 26(a) is a graph showing iSE measurement of SiO₂ EE-ALD film thickness at 35° C. using sequential H₂O doses as the oxygen source, and FIG. 26(b) is a graph showing thickness mapping of the film by ex situ SE.

FIG. 27 is a graph showing SiO₂ film thickness, density, and index of refraction dependence on Si₂H₆ exposure times.

FIG. 28(a) is a graph showing iSE measurement of SiO₂ EE-ALD film thickness at 35° C. using sequential O₃ doses as the oxygen source, and FIG. 28(b) is a graph showing thickness mapping of the film by ex situ SE.

FIG. 29 is a graph showing XPS depth profiling of the SiO₂ EE-ALD film using the O₃ process, wherein the film was deposited on a Si coupon; although the film seems to be Si rich, carbon contamination is below the noise level.

FIG. 30(a) is graph showing saturation curves for SiO₂ EE-ALD with O₃ process, and FIG. 30(b) is a graph showing growth rate dependence on bias grid voltage.

FIG. 31(a) is a photograph showing an uncoated AAO substrate as viewed from the top; FIG. 31(b) is a photograph showing an AAO substrate after 500 cycles of SiO₂ EE-ALD as viewed from the top; FIG. 31(c) is a graph showing pore diameter size distributions comparing the uncoated and coated AAO substrates as seen in FIG. 31(a) and FIG. 31(b), respectively; and FIG. 31(d) is an EDS line scan tracking the Si signal through a pore cross-section after the SiO₂ EE-ALD deposition.

FIG. 32 is a graph showing the thickness of a wet thermal oxide sample and an EE-ALD SiO₂ sample deposited with the sequential O₃ process after etching in a BOE solution for varying times as measured by ex situ SE.

FIG. 33 is a graph showing iSE thickness data during a 400 cycle SiO₂ EE-ALD co-dose θ₃|e⁻ process at 35° C.

FIG. 34(a) is a graph showing the saturation behavior of Si₂H₆, and FIG. 34(b) is a graph showing O₃|e⁻ exposure times for the SiO₂ EE-ALD O₃|e⁻ co-dose process.

FIG. 35 is a graph showing XPS depth profile data of a 400 cycle SiO₂ EE-ALD film deposited using the O₃|e⁻ co-dose process at 35° C.

FIG. 36 is a graph showing BOE rate comparisons.

### DETAILED DESCRIPTION OF EXAMPLE EMBODIMENTS

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future.

Throughout this disclosure, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this disclosure, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

As used herein, unless defined otherwise, all technical and scientific terms generally have the same meaning as commonly understood by one of ordinary skill in the art to which this disclosure belongs. Generally, the nomenclature used herein and the laboratory procedures in surface chemistry are those well-known and commonly employed in the art.

The term “about” as used herein can allow for a degree of variability in a value or range, for example, within 10%, within 5%, or within 1% of a stated value or of a stated limit of a range, and includes the exact stated value or range.

As used herein, the term “ALD” refers to atomic layer deposition, which is a thin film deposition method. In certain embodiments, the term “thin” refers to a range of thickness from about 0.1 nm to about 300 nm. ALD uses a self-limiting reaction sequence that deposits films in discrete steps limited by surface site chemical reactions. It produces continuous films with atomically controlled thicknesses, high conformality, and typically pinhole-free and atomically smooth surfaces. These are essential properties as design constraints push device technologies to ever smaller sizes.

Electrons can provide a non-thermal means to enhance thin film growth, including at low temperature. In particular, electrons can enhance atomic layer deposition (ALD) and facilitate ALD at low temperature. SiO₂ is an important dielectric material in semiconductor devices. This disclosure describes SiO₂ electron-enhanced ALD (EE-ALD) at a low temperature of 35C using a hollow cathode plasma electron source (HC-PES) with Si₂H₆ as the silicon precursor and O₃/O₂ or H₂O as the oxygen reactants. For purposes of this disclosure, silicon is considered a metal, and SiO₂ is considered a metal oxide. This disclosure also includes the use of other metal oxides, such as TiO₂, HfO₂, and ZrO₂. Further, this disclosure includes the use of various temperatures and temperature ranges, such as less than 300° C., less than 250° C., less than 200° C., less than 100° C., from 15° C. to less than 100° C., from 20° C. to less than 100° C., from 25° C. to less than 100° C., from 30° C. to less than 100° C., from 35° C. to less than 100° C., from 30° C. to 40° C., and about 35° C. In situ spectroscopic ellipsometry (SE) measurements are employed to measure the SiO₂ film thickness in real time. The SE analysis reveals that SiO₂ EE-ALD films nucleate immediately and grow linearly versus the number of cycles during SiO₂ EE-ALD. Because the HC-PES can deliver an electron beam into a chamber with a background gas present at pressures up to ˜5 mTorr, SiO₂ EE-ALD can also be performed by co-dosing electrons and the oxygen reactants.

A key aspect of this disclosure is the deposition of SiO₂ films at low temperatures such as 35C. This SiO₂ EE-ALD is SiO₂ EE-ALD performed without the need for plasma activation, halide precursors, or catalysts.

Low temperature SiO₂ deposition is needed to maintain a low thermal damage to prevent the damage of other devices.

Also, an advantage of this disclosure is that SiO₂ EE-ALD provides the deposition of SiO₂ at very low temperatures without using plasma, halogen, precursors or catalysts.

In addition to depositing low temperature SiO₂ films to be used as dielectric layers or spacers, SiO₂ EE-ALD can also be used to deposit SiO₂ coatings on various other devices at low temperatures. Applications include optical coatings, protective coatings, diffusion barrier coatings and electrically isolating coatings.

In a particular embodiment, this disclosure describes SiO₂ EE-ALD at a low temperature of 35° C. using the HC-PES with Si₂H₆ as the silicon precursor and O₃/O₂ or H₂O as the oxygen reactants. In situ spectroscopic ellipsometry (SE) measurements are employed to measure the SiO₂ film thickness in real time. The SE analysis reveals that SiO₂ EE-ALD films nucleate immediately and grow linearly versus the number of cycles during SiO₂ EE-ALD. Because the HC-PES can deliver an electron beam into a chamber with a background gas present at pressures up to ˜5 mTorr, SiO₂ EE-ALD can also be performed by co-dosing electrons and the oxygen reactants. As a general matter, the pressure is not a key feature in the method in this disclosure, and any suitable pressure can be used.

Electrons can enhance SiO₂ atomic layer deposition (ALD) using disilane (Si₂H₆) and either ozone (O₃/O₂) or water (H₂O) as the reactants. The electrons in this disclosure were produced by a hollow cathode plasma electron source operating with a grid bias of ≈−300 V. These electrons could irradiate a sample area of ˜2 cm×2 cm. SiO₂ electron-enhanced ALD (EE-ALD) was demonstrated at 35° C. by exposing the sample to sequential electron, oxygen reactant, and Si₂H₆ exposures. The electron exposure was an electron current of ˜150 mA for 3 s. The Si₂H₆ exposure was a Si₂H₆ pressure of 100 mTorr for 1.0 s. The oxygen reactant was either O₃ or H₂O at an oxygen reactant pressure of 0.5-1.0 Torr for 3 s.

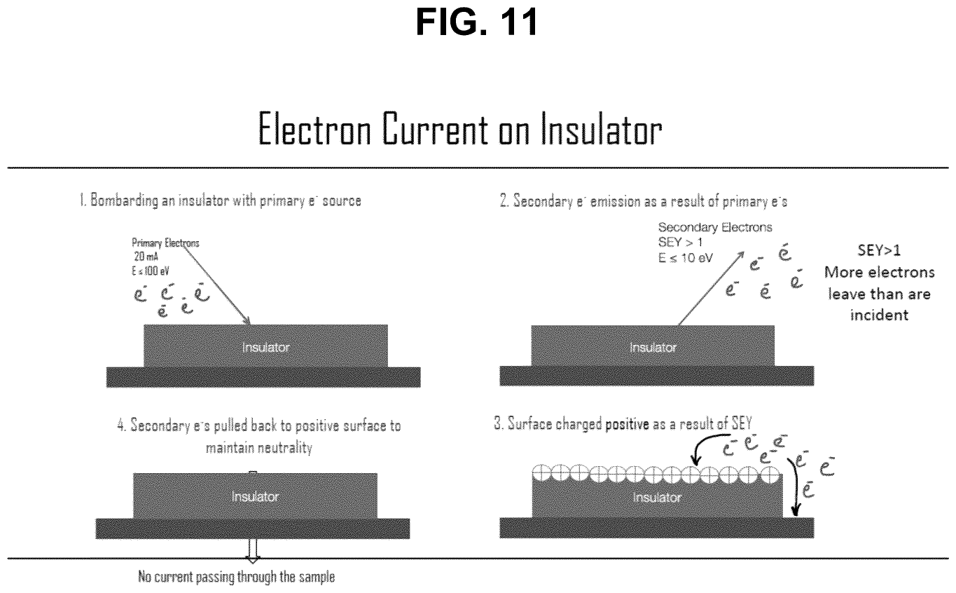

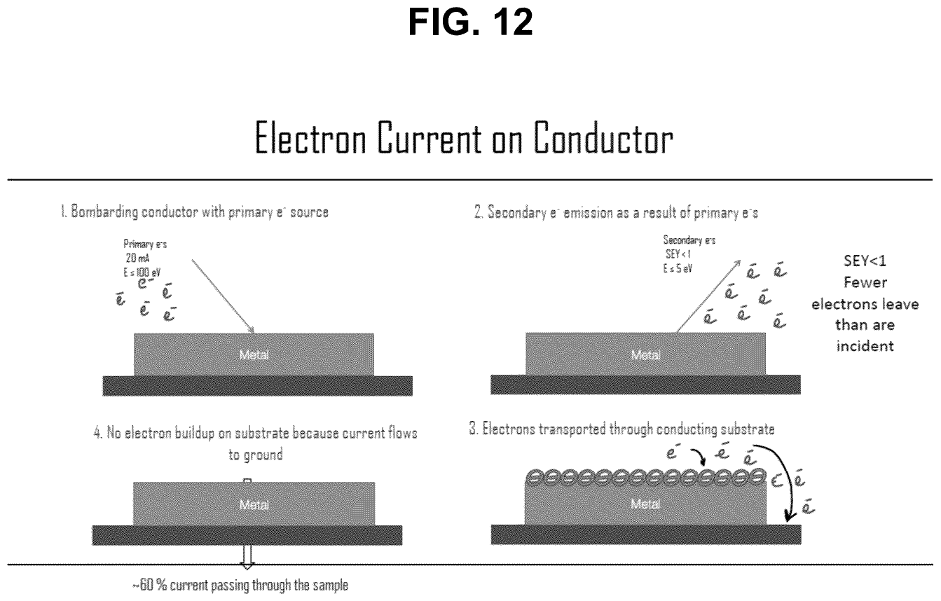

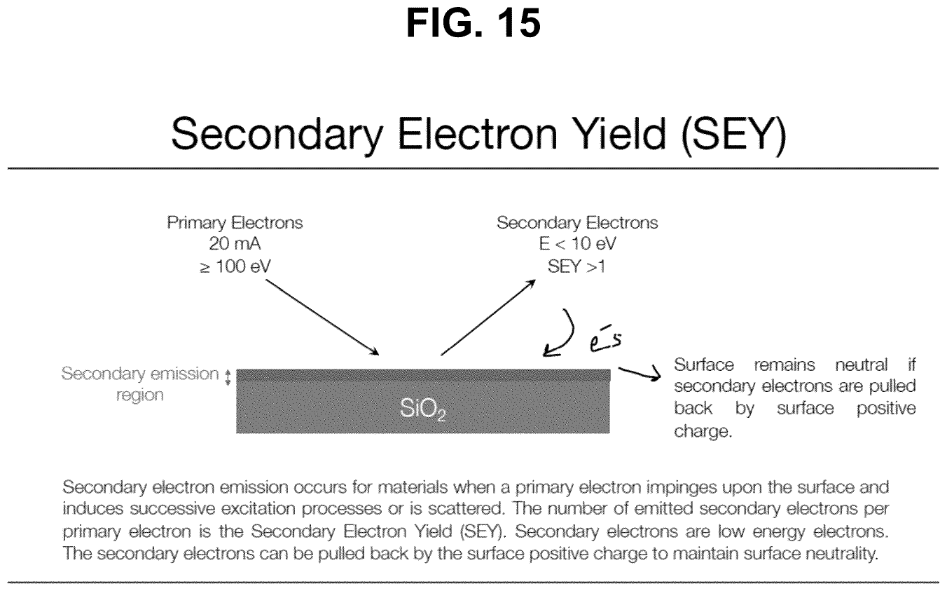

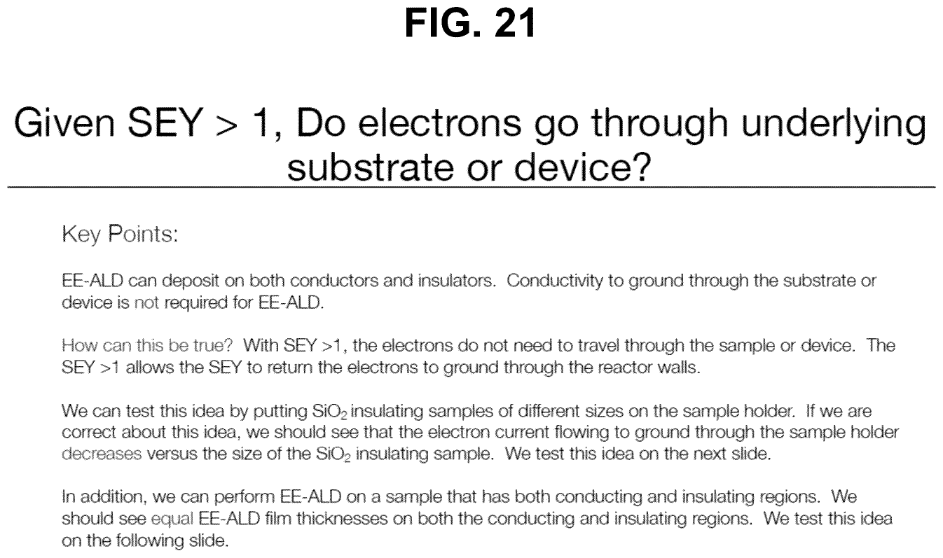

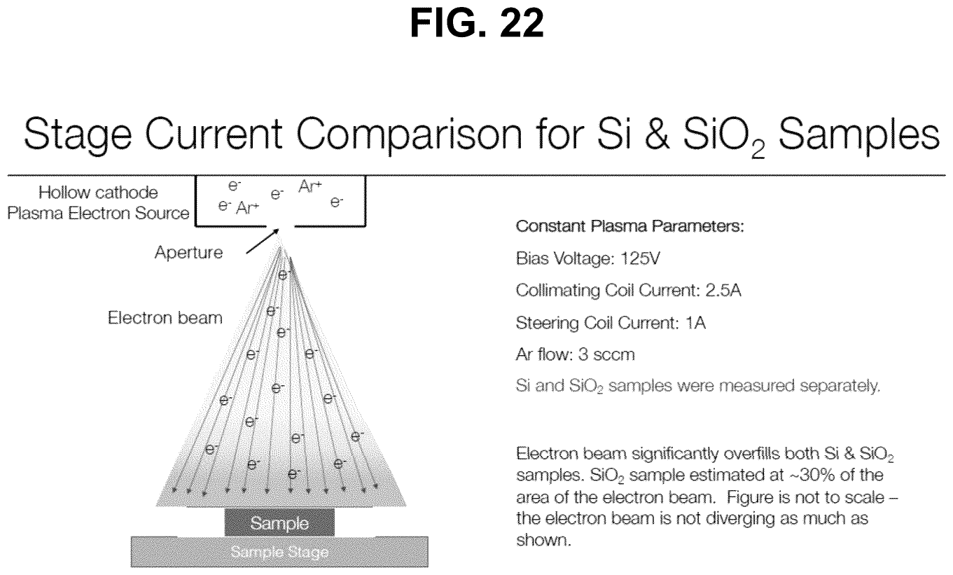

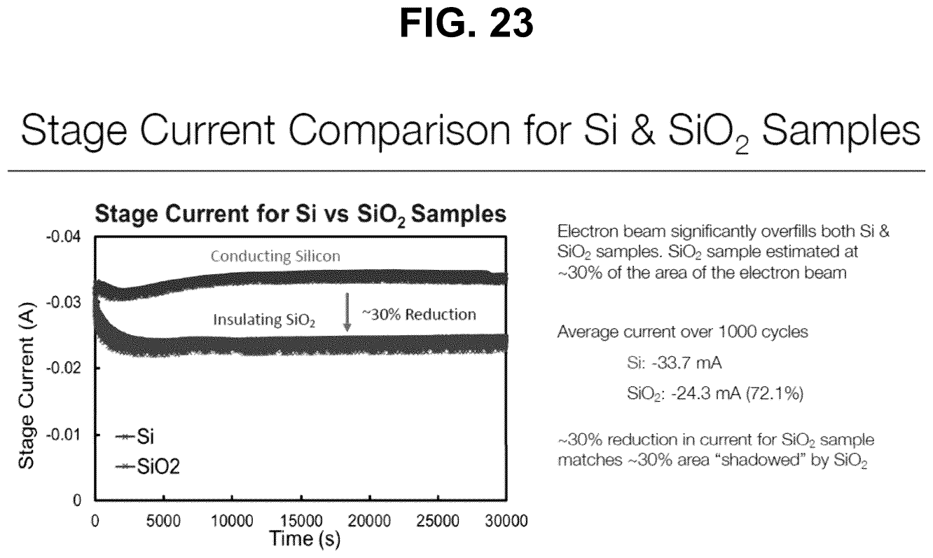

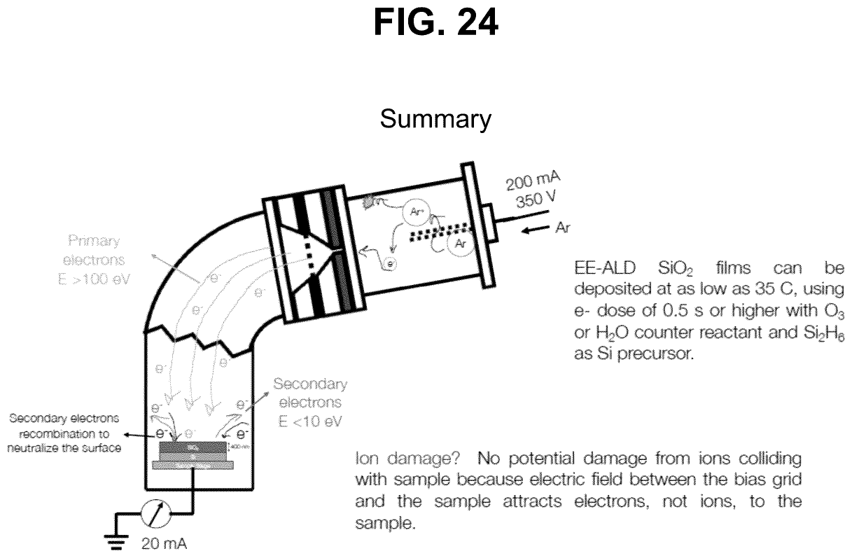

Spectroscopic ellipsometry measurements determined that SiO₂ EE-ALD films nucleated rapidly and deposited linearly versus number of EE-ALD cycles on silicon wafers. The SiO₂ EE-ALD growth rate was 0.89 Å/cycle using O₃ and 0.88 Å/cycle using H₂O. The SiO₂ growth rate was also self-limiting at higher electron and Si₂H₆ exposures. The SiO₂ EE-ALD films could be grown on conducting silicon wafers or insulating SiO₂ films. SiO₂ EE-ALD is possible on insulators because the secondary electron yield at ˜100-300 eV is greater than unity. The SiO₂ film charges positive and then pulls back secondary electrons to maintain charge neutrality. This is shown in FIG. 11, as opposed to FIG. 12, which shows the case of electron current on a conductor instead of an insulator. Secondary electron yield is explained in FIG. 15, and further discussion is shown in FIG. 21. See also FIGS. 22, 23, and 24.

The SiO₂ EE-ALD films had properties that were comparable with thermal SiO₂ oxides. The refractive indices of the SiO₂ EE-ALD films were n=1.44±0.02 and equivalent to the refractive index of a wet thermal SiO₂ oxide film. In addition, the SiO₂ EE-ALD films yielded etch rates in dilute buffered oxide etch solutions that were only slightly higher than the etch rate of a wet thermal SiO₂ oxide film. SiO₂ EE-ALD should be useful to deposit high quality SiO₂ films for various applications at low temperatures.

### EXAMPLES

Embodiments will now be illustrated by way of the following examples, which do not limit the embodiments in any way.

### I. Experimentation

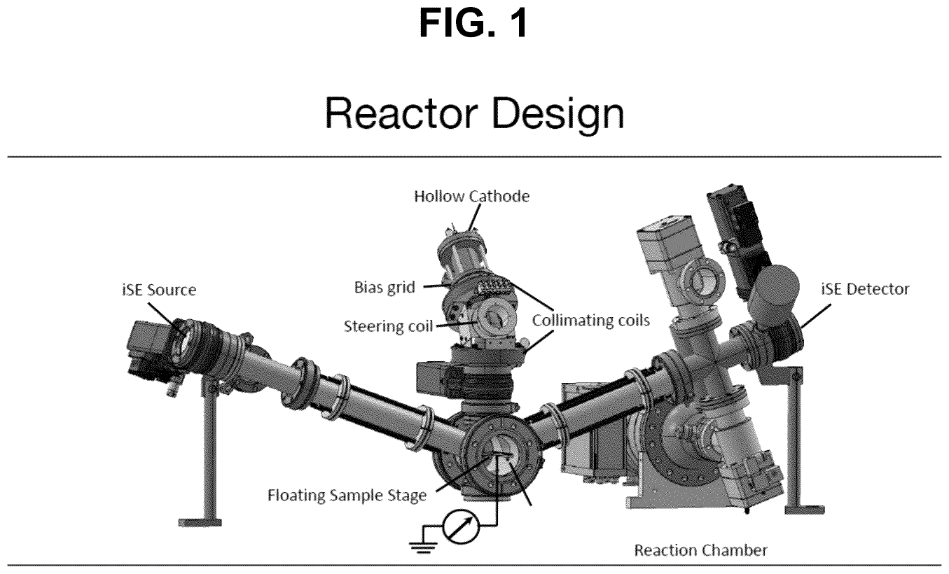

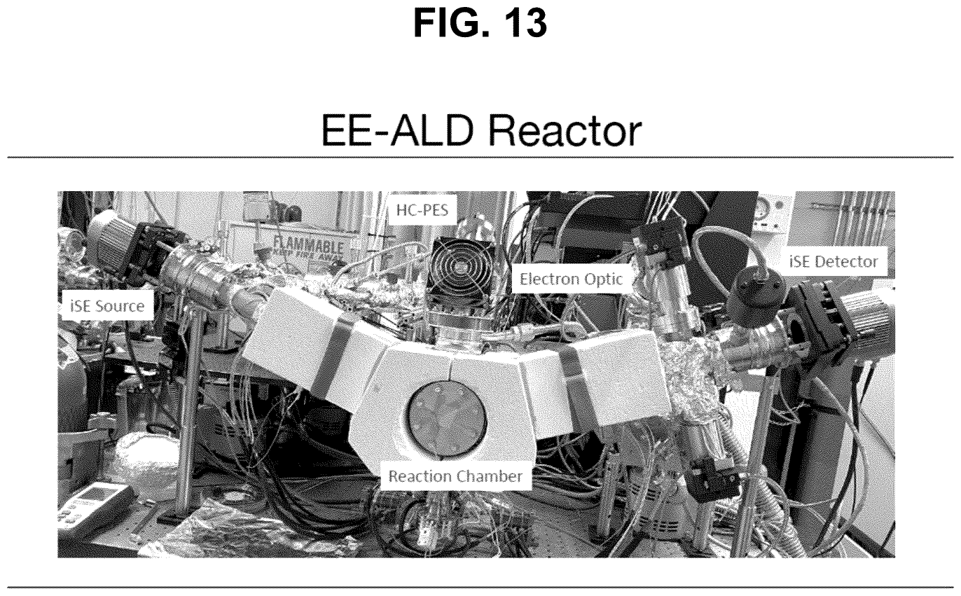

EE-ALD films were deposited in a V-shaped viscous-flow reactor with in situ spectroscopic ellipsometry (iSE, J. A. Woollam) capabilities. This reactor is similar in design to a previously reported V-shaped reactor. The reactor also had an HC-PES with electron optics to turn the electron beam to remove the sputtering flux from the output of the HC-PES as described previously. The aperture of the HC-PES was ˜28 cm from the sample surface. A CAD image of the main reactor body is shown in FIG. 1. Further details of the EE-ALD reactor are shown in FIG. 13.

The sample was mounted to a metal plate with spring clips. The plate was able to slide in and out of the reactor for ease of sample transfer. The plate was also electrically isolated from the main reactor for more accurate sample current measurements. Sample current was measured by a multimeter probe (Keithley, DMM7510 7.5 Digit Multimeter) connected to the sample stage.

Stage temperature was measured with a thermocouple probe inserted into the center of the stage. Temperature was defined by PID Eurotherm control (nanodac, Invensys) of 4 band heaters around the main chamber. The inlet arm, exhaust arm, and precursor lines of the reactor were also heated with additional band heaters, cartridge heaters, and fiberglass heat tapes that were controlled by Variac voltage transformers.

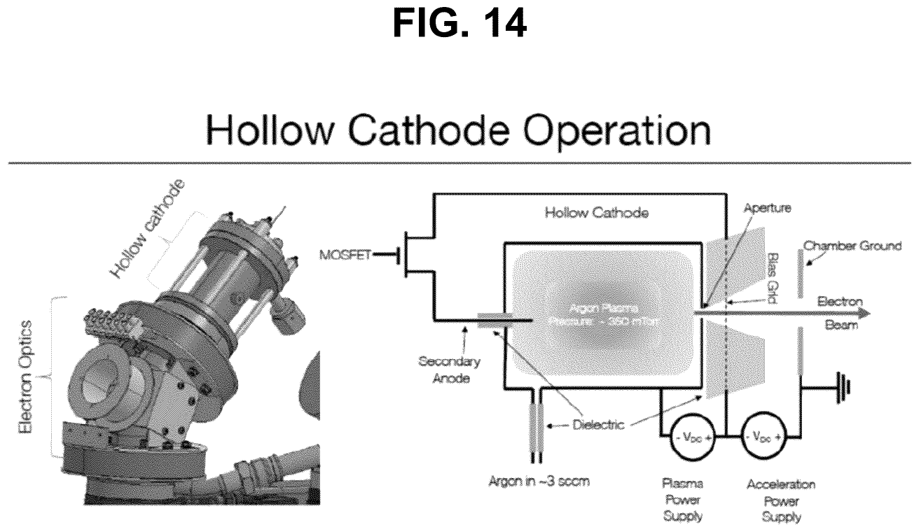

The HC-PES supplied electrons to the sample surface. The hollow cavity of the HC-PES was biased at −350 V relative to the bias grid voltage. The bias grid voltage was biased relative to ground and could be controlled to change the electron energy distribution. The bias grid voltage was variable between −50 and −300 V. Argon (Ar, 99.999%, Airgas) flow through the hollow cavity was 2.5 sccm controlled by a mass flow controller (MFC) (MKS, 14 sccm range). The hollow cathode operation is shown in FIG. 14.

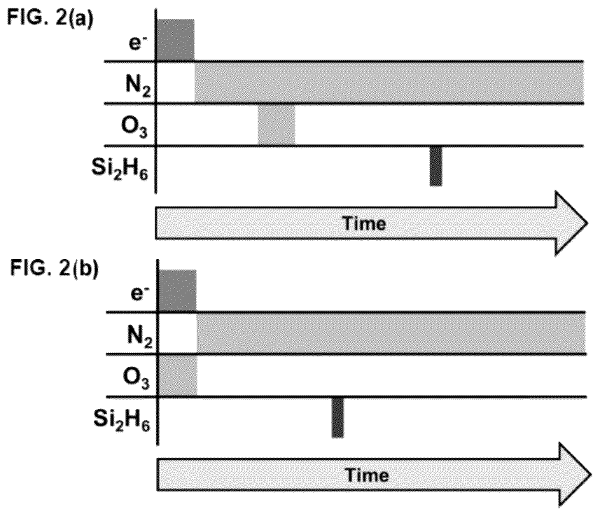

SiO₂ EE-ALD was performed using the process sequence shown in FIG. 2(a) and FIG. 2(b). For SiO₂ EE-ALD, electrons were pulsed sequentially with Si₂H₆ and either ozone (03, 5 wt % in O₂, LG-14 Corona Discharge Laboratory Ozone Generator) or deionized water. In this disclosure, the O₃/O₂ exposure will be designated as O₃ for convenience. The process sequence using O₃ as the oxidation reactant is displayed in FIG. 2(a). No gas, other than the Ar to sustain the hollow cathode plasma, was flowing during the electron beam pulse. During and after the O₃ (or H₂O) and Si₂H₆ exposures, nitrogen (N₂, 99.999, Airgas) was used as an inert carrier gas and purge gas. The O₃ (or H₂O) dose pressure transients were 0.5-1 Torr. The Si₂H₆ dose pressure transients were 50 mTorr. N₂ flow was controlled by an MFC (MKS, 200 sccm range) set to 100 sccm. This N₂ flow resulted in a reactor base pressure of 0.7 Torr.

An alternate SiO₂ deposition process consisted of co-dosing electrons with the oxygen source, O₃ or H₂O, followed by sequential dosing of Si₂H₆. The process sequence using O₃ as the oxidation reactant co-dosing with the electrons is displayed in FIG. 2(b). The co-dose process only had N₂ flowing during purging and the Si₂H₆ exposure. The bias grid voltage was typically set to −300 V for both the sequentially dosed and co-dosed processes.

Film growth was monitored with in situ spectroscopic ellipsometry (J. A. Woollam, iSE). SiO₂ films were deposited onto Si coupons with a native oxide. Ex situ spectroscopic ellipsometry with multiangle scan capabilities (J. A. Woollam, M-2000) was used to measure the SiO₂ film thickness and index of refraction using a Cauchy model.

Ex situ X-ray photoelectron spectroscopy (XPS, PHI 5600) depth profiling was used to measure the composition of the SiO₂ EE-ALD films. However, the Si:O ratio of the SiO₂ EE-ALD films could not be determined in the bulk due to preferential oxygen sputtering during depth profiling. Atomic Force Microscopy (AFM, NX10, Park Systems) was employed to measure film surface roughness of the SiO₂ EE-ALD films. Grazing incidence X-ray Diffraction (GIXRD) was used to characterize the crystallographic structure of the deposited films.

To assess film quality, SiO₂ EE-ALD films were etched in a diluted buffered oxide etch solution (dBOE, 5 mL buffered oxide etch 6:1 from Sigma-Aldrich in 95 mL DI H₂O). Etching in the dBOE occurred at 21° C. Film thicknesses were measured periodically by SE. Films were pre-cleaned with an acetone, isopropyl alcohol, DI H₂O rinse, and N₂ dry before being dipped in the dBOE for 10 s. Samples were then rinsed in a DI H₂O bath for 1 min, followed by further deionized H₂O rinsing under a faucet before drying with N₂. After this etching step, the film thickness was measured with multiangle SE. Subsequently, the films were dipped again in the dBOE for another 10 s and the process was repeated to progressively etch the SiO₂ film for a total of 40 s.

### II. Results and Discussion

A. SiO₂ EE-ALD Using Sequential Electron Beam, O₃, and Si₂H₆ Exposures

SiO₂ EE-ALD films were grown at 35° C. using the process sequence shown in FIG. 2(a) with sequential electron beam, O₃, and Si₂H₆ exposures. Before the SiO₂ EE-ALD, the sample was rinsed with acetone and IPA and dried with N₂ prior to loading. A 1 min O₃|e⁻ co-dose exposure was used to further clean the surface while under vacuum. One SiO₂ EE-ALD cycle consisted of an electron beam exposure for 3 s, purge for 5 s, O₃ exposure for 3 s, purge for 10 s, Si₂H₆ exposure for 1 s, and purge for 15 s. There was an N₂ gas flow of 100 sccm during the O₃ and Si₂H₆ exposures and during all purges.

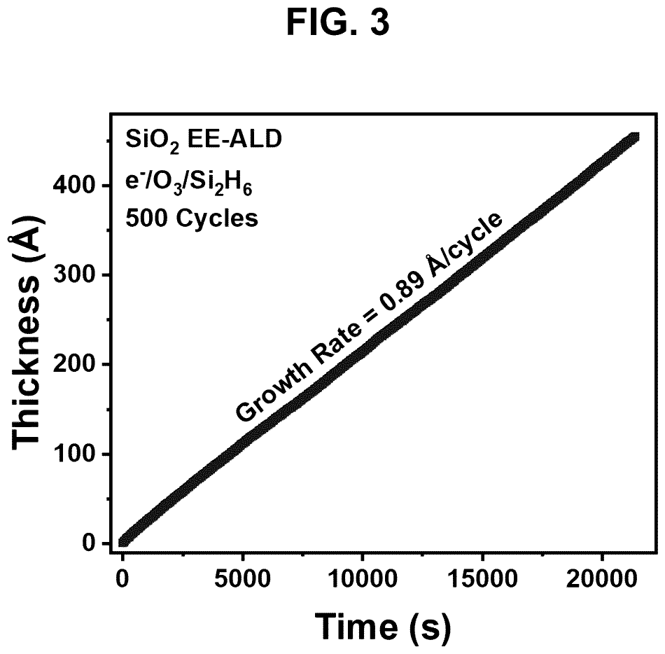

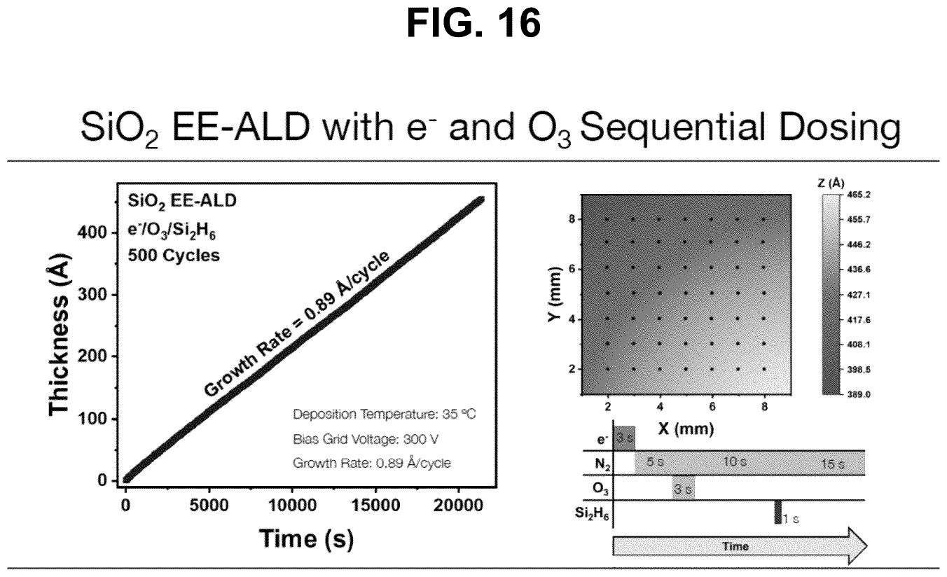

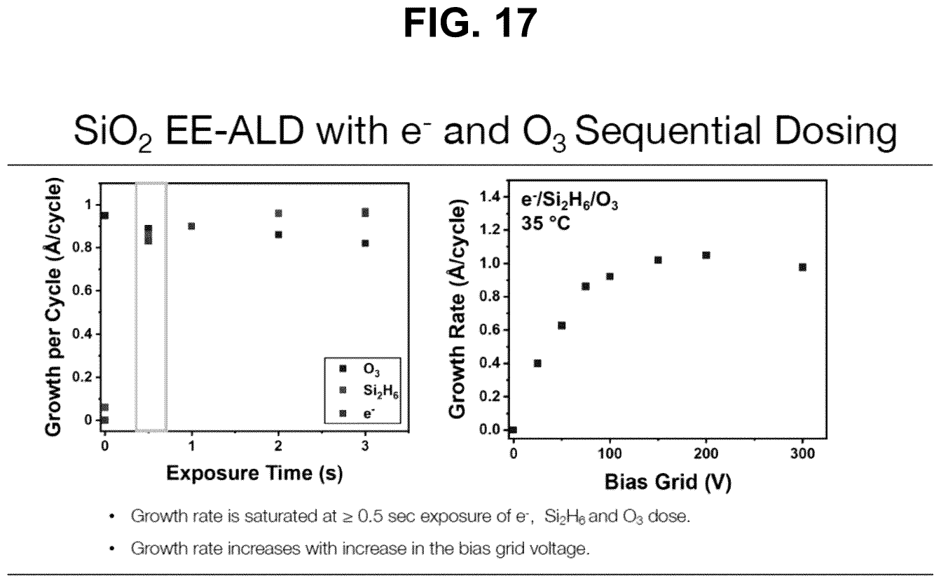

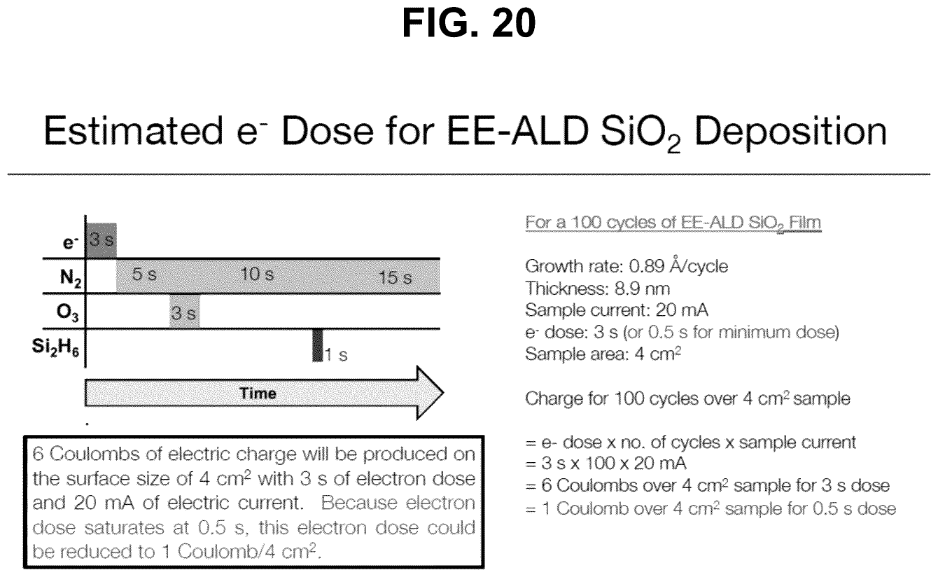

An SiO₂ EE-ALD film was deposited on a Si sample at 35° C. with a−300 V grid bias. FIG. 3 shows the results for 500 SiO₂ EE-ALD cycles. The iSE measurements were collected for 7 s, 8 s after the Si₂H₆ exposure. The SiO₂ EE-ALD growth is linear with time during the SiO₂ EE-ALD cycles with a cycle time of 37 s per cycle. A linear growth rate of 0.89 Å/cycle was observed with no nucleation delay. Further details are shown in FIGS. 16 and 17. See also FIG. 20.

The proposed surface processes during SiO₂ EE-ALD are as follows: The electron exposure forms active surface sites by electron stimulated desorption (ESD). O₃ can then react with the active surface sites to form surface oxygen species. Subsequently, Si₂H₆ can react with surface oxygen species or adsorb on active surface sites remaining from the ESD. The next electron exposure can then desorb hydrogen from SiH surface species resulting from Si₂H₆ adsorption and form reactive Si dangling bond sites. O₃ can then react with these reactive sites to oxidize the silicon surface species and form surface oxygen species. Si₂H₆ can again react with surface oxygen species or adsorb on active surface sites remaining from the ESD.

The film thickness was mapped using multiangle ex situ SE. This mapping revealed a slight thickness gradient resulting from a minor misalignment of the electron beam from the center of the sample. The index of refraction from the ex situ multiangle SE Cauchy model fit was n=1.457+0.00343/λ² with a low mean squared error (MSE) of 3.190. In addition, AFM measurements of the surface roughness also confirmed smooth SiO₂ EE-ALD films with a root mean square (RMS) roughness of <2 Å.

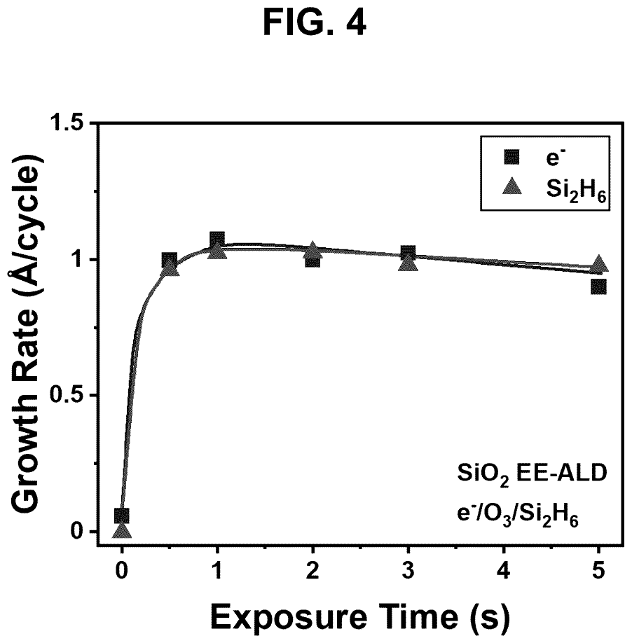

The growth rate versus the electron beam and Si₂H₆ exposure times during SiO₂ EE-ALD using sequential electron, O₃, and Si₂H₆ exposures at 35° C. is shown in FIG. 4. Each growth rate point is an average of the last 20 cycles of a deposition lasting 25 cycles. The nominal sequence for one SiO₂ EE-ALD cycle was: 3 s electron beam exposure, 5 s purge, 3 s O₃ exposure, 10 s purge, 1 s Si₂H₆ exposure, and 15 s purge. The solid squares show the growth rate dependence on the electron beam exposure time with the Si₂H₆ exposure time fixed at 1 s. The solid triangles show the growth rate dependence on the Si₂H₆ exposure time with the electron beam exposure time fixed at 3 s. The SiO₂ EE-ALD growth rate saturates readily versus the electron beam and Si₂H₆ exposure times.

The SiO₂ EE-ALD growth rate was also examined versus the O₃ exposure time. However, SiO₂ film growth was observed even with no O₃ exposure time. SiO₂ film growth may occur with residual H₂O desorbing from the chamber walls. The surface after the electron beam exposure contained dangling bonds which were highly reactive. Residual H₂O may have been able to easily deposit on this reactive surface.

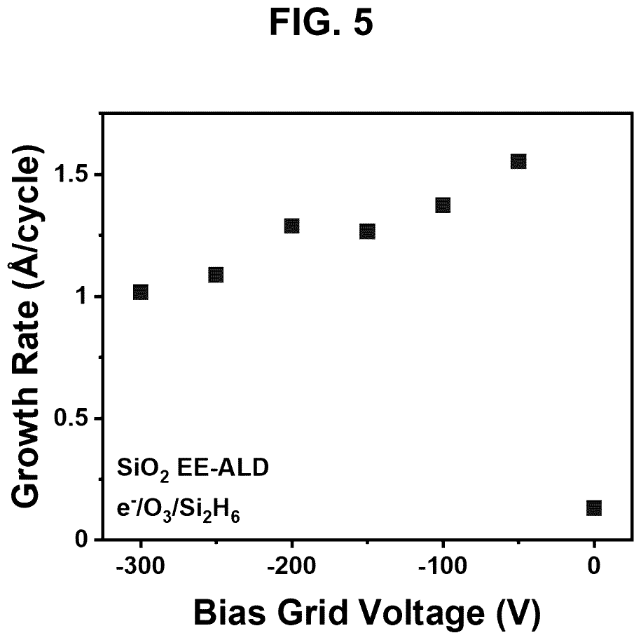

Additional experiments explored the dependence of SiO₂ EE-ALD on the bias grid voltage. The voltage was varied from −50 V to−300 V. The SiO₂ EE-ALD growth rate versus the bias grid voltage is shown in FIG. 5. Each data point is an average growth rate from deposition over 20 cycles with an SiO₂ EE-ALD cycle consisting of: 3 s electron beam exposure, 5 s purge, 3 s O₃ exposure, 10 s purge, 1 s Si₂H₆ exposure, and 15 s purge. The lower growth rates at the higher negative bias grid voltages may suggest higher density films with less hydrogen or hydroxyl contamination at the higher negative bias voltages. Alternatively, there may be a small competitive etch or selective desorption of oxygen at these higher negative grid biases.

B. SiO₂ EE-ALD Using Sequential Electron Beam, H₂O and Si₂H₆ Exposures

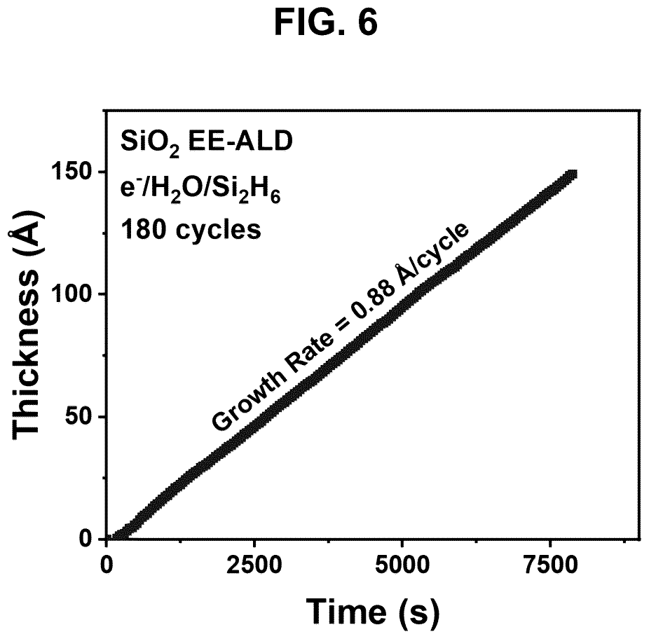

SiO₂ EE-ALD films were also grown at 35° C. with a−300 V grid bias using the process sequence shown in FIG. 2(a) where H₂O was the oxygen source instead of O₃. FIG. 6 shows the results for 180 SiO₂ EE-ALD cycles. The iSE measurements were collected 8 s after the Si₂H₆ exposure. The SiO₂ EE-ALD growth is linear with time during the SiO₂ EE-ALD cycles with a cycle time of 37 s per cycle. A linear growth rate of 0.88 Å/cycle was observed with no nucleation delay. The results in FIG. 3 and FIG. 6 are nearly equivalent. These results suggest that the SiO₂ EE-ALD is not sensitive to the oxygen reactant. Since SiO₂ EE-ALD was observed even with no H₂O exposure, another possibility is that the background H₂O dominated the silicon oxidation in the SiO₂ EE-ALD process.

### C. SiO₂ EE-ALD Using Different Reaction Sequences

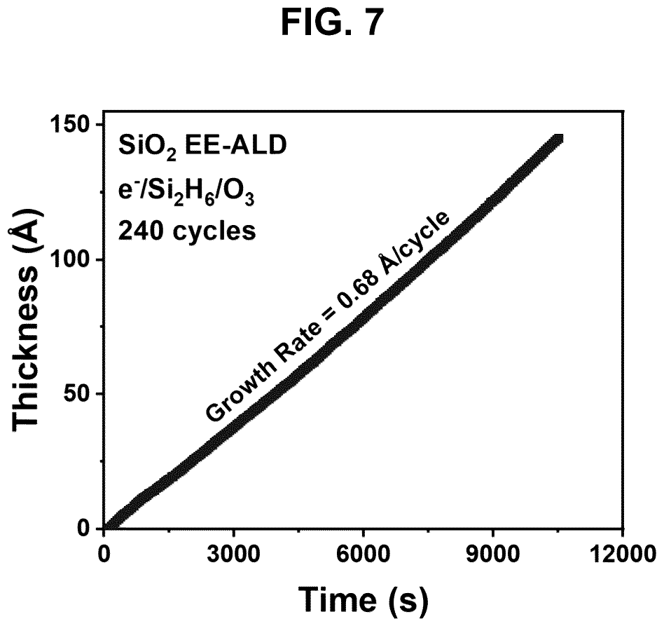

SiO₂ EE-ALD was also performed using a different reaction sequence where the electron exposure was performed after the oxygen reactant exposure. The results for SiO₂ EE-ALD using the sequence e⁻/Si₂H₆/O₃ is shown in FIG. 7. Similar to the other SiO₂ EE-ALD growth curves shown in FIGS. 3 and 6, the SiO₂ growth is linear and the nucleation of the SiO₂ film is immediate. This process sequence yielded a smaller growth rate of 0.68 Å/cycle. In comparison, a growth rate of 0.89 Å/cycle was obtained using the sequence e⁻/O₃/Si₂H₆ shown in FIG. 3. Likewise, a growth rate of 0.88 Å/cycle was obtained using the sequence e⁻/H₂O/Si₂H₆ shown in FIG. 6.

The SiO₂ growth rate was measured to be higher when the electron exposure is directly after the Si₂H₆ exposure. This sequence may result in the desorption of the most hydrogen from SiH surface species. This would result in the most reactive silicon dangling bond sites for the following O₃ exposure. Similar experiments were performed with the sequence e⁻/Si₂H₆/H₂O. This sequence yielded an even smaller SiO₂ EE-ALD growth rate of 0.52 Å/cycle.

D. SiO₂ EE-ALD by Co-Dosing Electron Beam with Oxygen Reactant

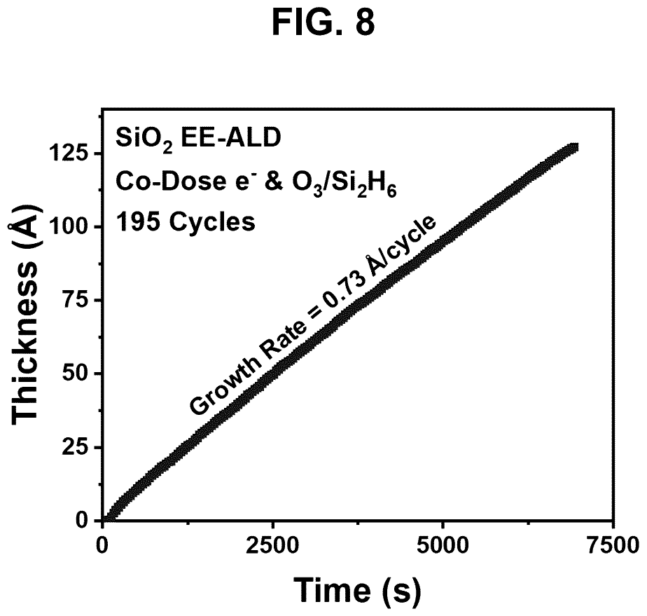

Additional SiO₂ EE-ALD films were grown by co-dosing the electron beam and either O₃ or H₂O together with Si₂H₆ using the process sequence shown in FIG. 2(b). These SiO₂ EE-ALD films were also grown at 35° C. with a−300 V grid bias. FIG. 8 shows the results for 195 SiO₂ EE-ALD cycles using O₃ as the oxygen reactant for the electron beam/O₃ co-dosing. During the co-dose exposures, the oxygen source pressure was <5 mTorr. The co-dose cycle consisted of a 3 s co-dose O₃|e⁻ exposure (or H₂O|e⁻ exposure), 10 s purge, 1 s Si₂H₆ exposure, 15 s purge. The iSE measurements were collected 8 s after the Si₂H₆ exposure. The SiO₂ EE-ALD growth is linear with time during the SiO₂ EE-ALD cycles with a cycle time of 29 s per cycle. A linear growth rate of 0.73 Å/cycle was observed with no nucleation delay.

During the co-dosing of the electron beam with the oxygen reactant, the electron beam can interact with the oxygen reactant in the gas phase. Electron impact could lead to the dissociation of O₃ or H₂O. O₂ is the main component of the O₃/O₂ exposure. The cross section for O₂ dissociation by electron impact at 200 eV is 3×10⁻¹⁷ cm². The cross section for H₂O dissociation by electron impact at 300 eV is 1×10⁻¹⁶ cm². Similar cross sections are also observed for the ionization of O₂ or H₂O. The radical or ion species from this electron impact could adsorb on the growing SiO₂ film. However, the lower growth rate for SiO₂ EE-ALD when co-dosing of the electron beam with the oxygen reactant indicates that the possible adsorption of these reactive species does not increase the growth rate for SiO₂ EE-ALD.

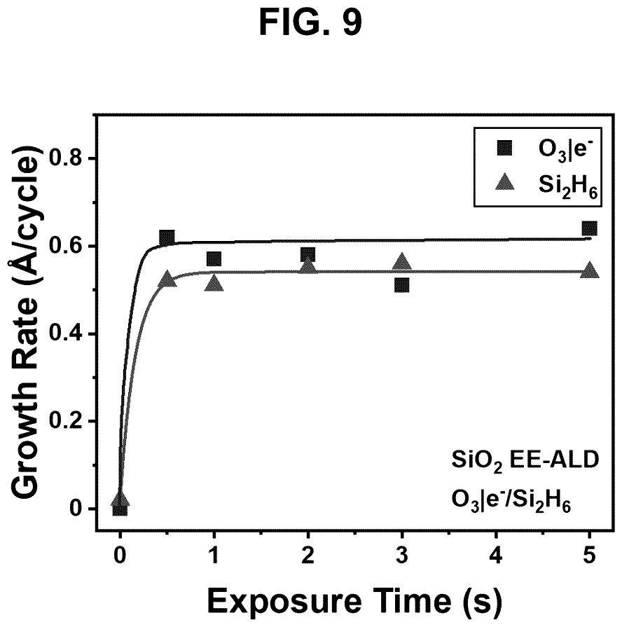

The self-limiting nature of the SiO₂ growth versus co-dosing O₃/electrons and Si₂H₆ was also explored using the process sequence in FIG. 2(b). The SiO₂ growth rate versus the O₃/electron beam and Si₂H₆ exposure times at 35° C. is shown in FIG. 9. The nominal process conditions were 3 s O₃|e⁻ (or H₂O|e⁻) co-dose, 10 s purge, 1 s Si₂H₆ dose, and 15 s purge. Each data point represents the growth rate determined from an average of 20 cycles. The solid squares show the growth rate dependence on the co-dose O₃/electron exposure time with the Si₂H₆ exposure time fixed at 1 s. The solid triangles show the growth rate dependence on the Si₂H₆ exposure time with the co-dose O₃/electron exposure time fixed at 3 s. N₂ at 100 sccm was used as the inert carrier gas during the Si₂H₆ exposure and the purges. No N₂ was flowing during the O₃ or H₂O|electron beam co-dosing.

FIG. 9 shows that the SiO₂ growth rate saturates with increasing exposure time of either the O₃/electron exposure or the Si₂H₆ exposure. In these experiments, the SiO₂ growth rate was self-limiting at 0.55-0.60 Å/cycle. These growth rates are slightly lower than the growth rate of 0.73 Å/cycle measured for the results in FIG. 8. The growth rates may be lower because they were determined using only 20 SiO₂ EE-ALD cycles. Similar experiments were performed to explore the self-limiting nature of the SiO₂ growth versus co-dosing H₂O/electrons and Si₂H₆. These experiments also revealed that the SiO₂ growth was self-limiting versus the co-dosing H₂O/electron exposures and the Si₂H₆ exposures.

### E. SiO₂ Growth Rates, Refractive Indices, and Etch Rates for Different Process Conditions

The SiO₂ EE-ALD growth rates for the different process conditions are given in Table 1 below.

TABLE 1
Growth rate, index of refraction (λ → ∞), and diluted
buffered oxide etch rate values of the varying SiO₂ EE-ALD films
using sequential (s.) or co-dose (c.) parameters. 300 nm wet
thermal oxide index and dBOE rate data is also listed for comparison.

| | Growth Rate | Index of | dBOE |
|---|---|---|---|
| Sample | (Å/cycle) | Refraction | (Å/s) |
| s.O₃/Si₂H₆ | 0.89 | 1.457 | 2.166 ± 0.019 |
| s.H₂O/Si₂H₆ | 0.88 | 1.443 | 2.378 ± 0.109 |
| s.Si₂H₆/O₃ | 0.68 | 1.445 | 2.670 ± 0.129 |
| s.Si₂H₆/H₂O | 0.52 | 1.438 | 2.316 ± 0.137 |
| c.O₃ | 0.73 | 1.417 | 2.377 ± 0.052 |
| c.H₂O | 0.59 | 1.437 | 2.786 ± 0.004 |
| Wet Thermal SiO₃ | — | 1.447 | 0.943 ± 0.068 |

The highest growth rates of 0.88-0.89 Å/cycle are observed for the sequential electron beam, oxygen reactant and Si₂H₆ exposures as shown in FIG. 2(a). The lowest SiO₂ EE-ALD growth rates of 0.52-0.73 Å/cycle are observed for the process sequence where the electron exposures are after the oxygen reactant exposure or when the electron beam and oxygen reactant are co-dosed as shown in FIG. 2(b).

The refractive indices were also measured for each process condition after SiO₂ EE-ALD using ex situ multiangle spectroscopic ellipsometry. The refractive index values were similar for all the process conditions. The refractive index was measured to be n_{∞}=1.44±0.02. This refractive index is nearly identical to the refractive index measured for SiO₂ film prepared by wet thermal oxidation of a silicon wafer. These SiO₂ wet thermal oxide films were prepared by University Wafer at a process temperature of 900-1050° C.

SiO₂ films were analyzed with ex situ XPS to characterize film purity. XPS depth profile elemental analysis showed high quality SiO₂ films as deposited by EE-ALD with carbon atomic percent in the bulk of the films below the detection limit of the instrument. Unfortunately, depth profiling was not able to determine an accurate Si:O ratio, due to preferential O sputtering. In addition, ex situ GIXRD was used to analyze the crystallographic structure of the EE-ALD SiO₂ films. Films were determined to be amorphous.

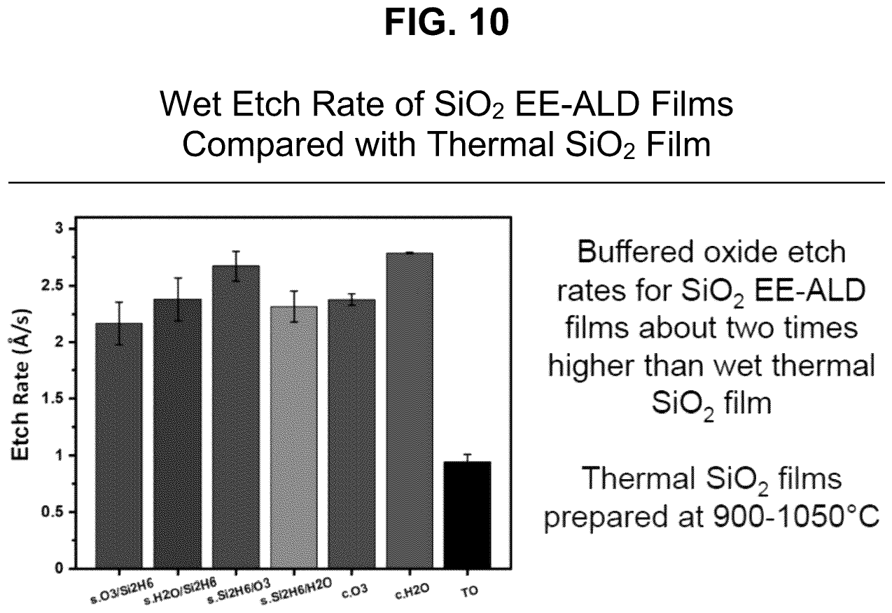

All of the SiO₂ EE-ALD films were also evaluated by measuring their dilute buffered oxide etch rates. The etch rates are shown in FIG. 10 and also included in Table 1. Each SiO₂ EE-ALD film had a starting thickness of ˜125 Å. The wet thermal oxide had a starting thickness of 3,248 Å. The SiO₂ films were etched in the dilute buffered oxide etch solution for 10 s at a time. The SiO₂ films were etched for a total time of 40 s. The SiO₂ film thicknesses were evaluated by spectroscopic ellipsometry measurements after etching for 20 s, 30 s, and 40 s. The SiO₂ film thicknesses versus etch time were fit to obtain the SiO₂ etch rates. The Cauchy values for the fits to the ellipsometry results was kept constant versus thickness and between the samples.

The etch rates for all the SiO₂ EE-ALD films were consistent across the various process sequences. The lowest SiO₂ etch rate was 2.166±0.019 Å/s for the e⁻/O₃/Si₂H₆ process sequence. The highest SiO₂ etch rate was 2.786±0.004 Å/s for the co-dose e⁻ & H₂O/Si₂H₆ process sequence. The etch rate for the wet thermal oxide was 0.943±0.068 Å/s. SiO₂ EE-ALD films have slightly faster etch rates than the wet thermal oxide SiO₂ films. However, these slightly larger etch rates are consistent with high quality SiO₂ films for all SiO₂ EE-ALD processes.

### F. EE-ALD on Insulating SiO₂ Substrates

These studies reveal that electron currents on insulating SiO₂ substrates can grow SiO₂ EE-ALD films. This behavior may be surprising because the initial expectation is that primary electron currents on an insulating substrate may charge the substrate negatively. This negative charge would then establish a voltage that would repel additional electron current, preventing EE-ALD. However, if the secondary electron yield, 6, is greater than unity, the sample would emit more electrons than impinge on it from the primary electron beam. This would create a positive charge on the sample surface. This positive charging would create a voltage that pulls back just enough secondary electrons to maintain a constant low surface charge.

For a continuous electron current, the insulator with δ>1 would charge to a voltage where the number of secondary electrons having enough energy to escape would equal the number of incident primary electrons. If the sample begins to charge more negatively, more secondary electrons will be emitted, reducing the negative charge. If the sample begins to charge more positively, more secondary electrons will be pulled back onto the sample, reducing the positive charge until the rate of primary electrons hitting the sample is equal to the rate of secondary electrons leaving the sample. Under these equilibrium conditions, there is no additional charging and the SiO₂ EE-ALD can proceed without complication. Only the primary incident electron energy may be increased slightly resulting from the positive voltage determined by the constant low surface charge on the insulating SiO₂ substrate. Measurements for SiO₂ reveal that 6 is greater than 1 for primary electron energies from ˜100-1000 eV. These secondary electron yields greater than unity allow EE-ALD to be performed on SiO₂ and other insulating substrates.

In addition to maintaining a low constant surface charge, the high secondary electron yields from SiO₂ may also influence the surface chemistry during SiO₂ EE-ALD. Earlier studies of the effect of low energy electron bombardment on O₂ oxidation of silicon observed the largest enhancement of silicon oxidation at electron energies that produced the highest secondary electron yields. The previous demonstration of SiO₂ electron-induced CVD using Si₂H₆ and O₂ as the reactants also observed larger SiO₂ growth rates at electron energies that yielded the largest secondary electron yields.

### III. Conclusions from Experimentation

The experimentation explored the ability of electrons to enhance SiO₂ atomic layer deposition (ALD) using disilane (Si₂H₆) and either ozone (O₃/O₂) or water (H₂O) as the reactants. SiO₂ electron-enhanced ALD (EE-ALD) was demonstrated at 35° C. by exposing the sample to sequential electron, oxygen reactant, and Si₂H₆ exposures. SE measurements determined that SiO₂ EE-ALD films nucleated rapidly and deposited linearly versus number of EE-ALD cycles on silicon coupons with a native oxide. The SiO₂ EE-ALD growth rate was 0.89 Å/cycle using O₃/O₂ and 0.88 Å/cycle using H₂O. The SiO₂ growth rate was also self-limiting at higher electron and Si₂H₆ exposures. The SiO₂ EE-ALD films could also be grown by co-dosing the electron and oxygen reactant exposures in sequence with the Si₂H₆ exposure.

The SiO₂ EE-ALD films could be grown on conducting silicon wafers or insulating SiO₂ films. SiO₂ EE-ALD is believed to be possible on insulating SiO₂ films because the secondary electron yield for SiO₂ at electron energies of ˜100-300 eV is greater than unity. Under these conditions, the SiO₂ film charges positive during electron exposure and then pulls back secondary electrons to maintain a small positive bias of a few volts.

The SiO₂ EE-ALD films had properties that were comparable with thermal SiO₂ oxides. The refractive indices of the SiO₂ EE-ALD films were similar for the various process conditions at n=1.44±0.02 and equivalent to the refractive index of a wet thermal SiO₂ oxide film. In addition, all the SiO₂ EE-ALD films yielded dilute buffered oxide etch rates that were only slightly higher than twice the etch rate of a wet thermal SiO₂ oxide film. SiO₂ EE-ALD should be useful to deposit high quality Si and SiO₂ films for various applications at low temperatures.

This disclosure also includes the following main elements:

1. A new low-temperature process (which is conducted below 100° C., and can be conducted as low as room temperature, which is about 15° C. to 28° C.) can be used to deposit a high quality SiO₂ film. For example, the process can be conducted at 15° C. to less than 100° C., or the process can be conducted at 20° C. to less than 100° C., or the process can be conducted at 25° C. to less than 100° C., or the process can be conducted at 30° C. to less than 100° C., or the process can be conducted at 35° C. to less than 100° C. As a more specific example, the process can be conducted at a temperature of 30° C. to 40° C.

2. The process includes the use of electrons (with −100 eV energy) delivered to the deposition substrate in an ALD (pulsed) fashion.

3. The process includes the use of common precursor gases such as SiH₄, H₂O, O₂, and O₃ that normally requires a high temperature for deposition (in thermal ALD and thermal CVD).

4. The process includes the optional use of a reactive background gas such as H₂O, O₂, or O₃ at low pressures. This is a new mode of deposition, different from previous EE-ALD processes.

5. The process does not require thermal or plasma activation of the precursor gases that are required in other ALD or CVD processes.

6. The process does not involve generating ions to bombard the surface, and thus does not damage the surface.

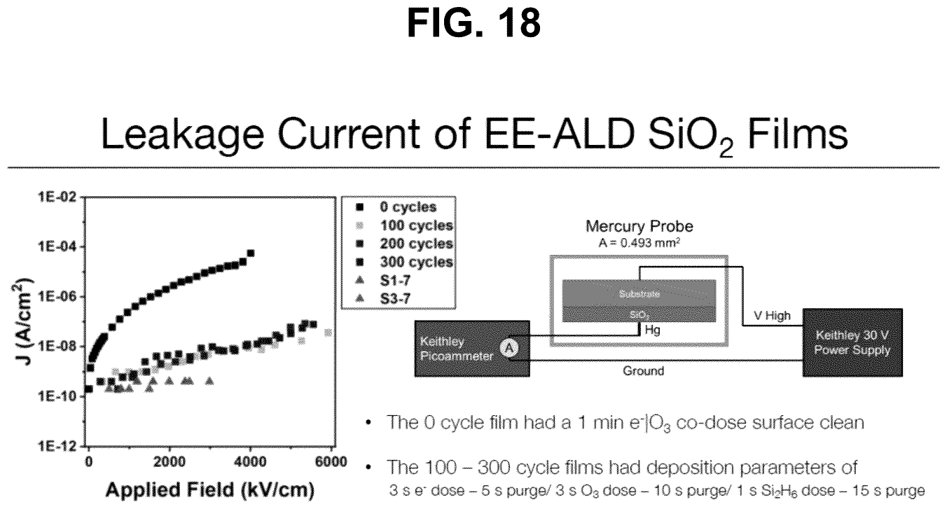

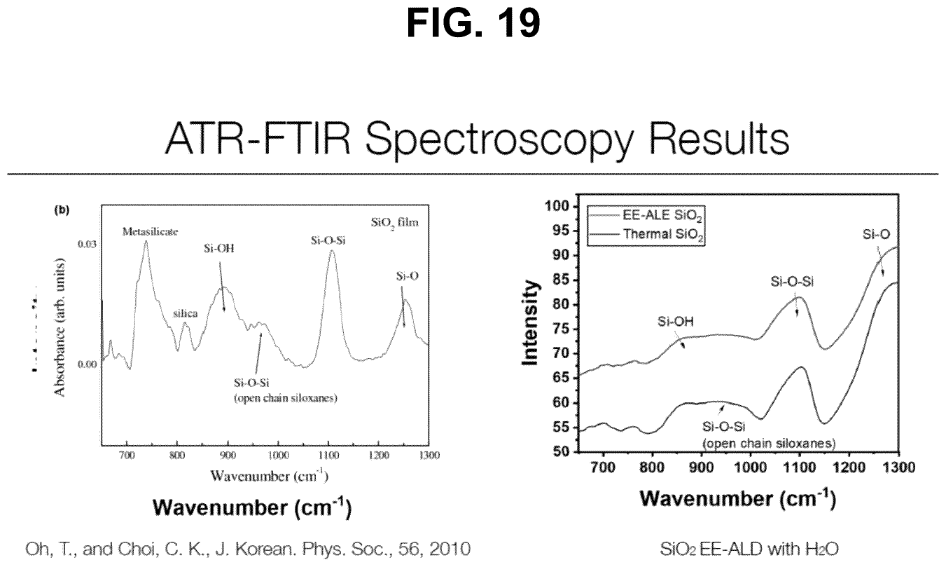

7. EE-ALD SiO₂ films that have been deposited had been measured and characterized to have properties that are comparable to high-quality thermal oxide (deposited at much higher temperatures), i.e. density, composition (close to stoichiometric), optical index of refraction, resistance to buffered oxide wet etch chemistry, and leakage current. See FIGS. 18 and 19.

8. EE-ALD SiO₂ films are superior compared with lower density CVD SiO₂ films, e.g., for STI (Shallow Trench Isolation) applications, and CVD SiO₂ films typically require a separate high T annealing step. EE-ALD SiO₂ does not require any annealing step, and can be deposited at low temperature.

9. EE-ALD SiO₂ films can enable chip fabrication and 3D heterogeneous processing requiring SiO₂ film deposition at low temperature (450° C. and lower).

10. Direct data shows that deposition of smooth blanket films are possible, but deposition in patterned structures can be provided as well.

11. In EE-ALD SiO₂, there is little risk of electron induced damage, since all or almost all of the electrons do not go through the deposition sample. The results are summarized in the schematic drawings shown in FIGS. 11 and 12. This is another advantage of EE-ALD process, compared to plasma enhanced or laser or photo enhanced deposition techniques.

The EE-ALD approach illustrated in FIGS. 2(a) and 2(b) for SiO₂ EE-ALD could also be extended to many other binary compounds. Possible ALD metal precursors are Ti(N(CH₃)₂)₄, WF₆, Al(CH₃)₃, and Mg(Cp)₂, which could replace Si₂H₆ in FIGS. 2(a) and 2(b). Possible co-reactants are H₂O, NH₃, PH₃ and H₂S, which could replace O₃ in FIGS. 2(a) and 2(b). These co-reactants would provide pathways for the EE-ALD of oxides, nitrides, phosphides and sulfides, respectively.

### Further Discussion

A further discussion of electron enhanced deposition of low-temperature SiO₂ films is set forth below.

### Overview:

Electron-Enhanced Atomic Layer Deposition (EE-ALD) is used to deposit low temperature SiO₂ films at 35° C. using either H₂O or O₃ as oxygen sources. The deposition process is tuned to give high performance SiO₂ with regards to index of refraction and buffered oxide etch (BOE) rates.

Improving the SiO₂ EE-ALD H₂O Process:

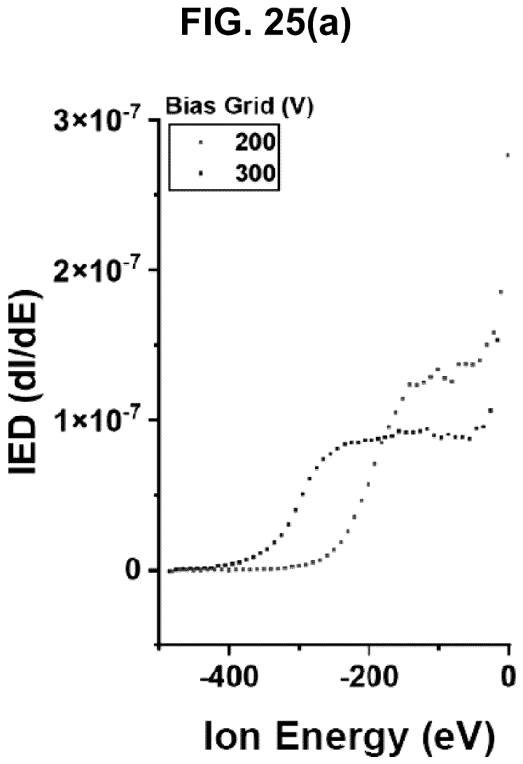

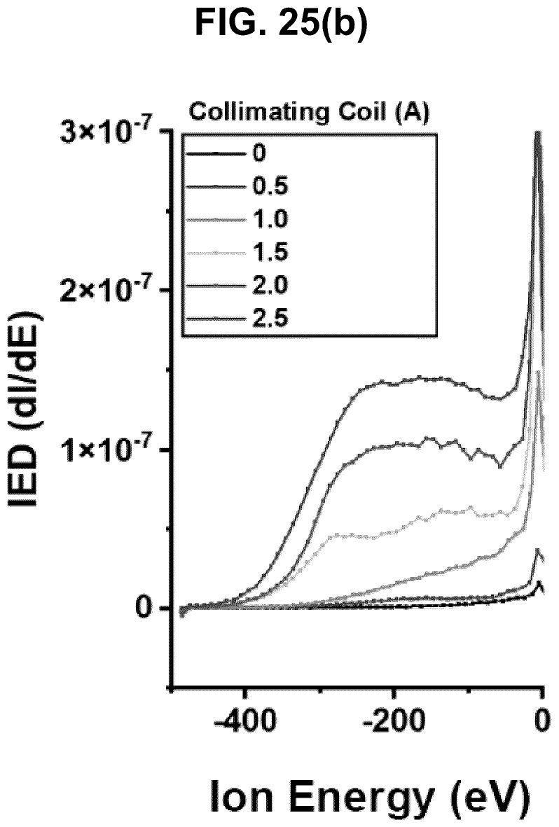

The EE-ALD V-shaped reactor uses electromagnetic steering and collimating coils to collimate and direct the electron beam from the hollow cathode to the sample surface. These coils were optimized by tuning the coil currents to allow for the highest ion energy distribution (IED) at the sample surface. IED and sample ion energy (here electron energy) were measured using an in situ retarding field energy analyzer (Impedans Semion Single Sensor Ion Analyzer). The optimization curves during tuning of the bias grid voltage and collimating coil currents are shown in FIG. 25(a) and FIG. 25(b), respectively. SiO₂ EE-ALD films were then deposited using the optimized hollow cathode bias grid and coil parameters for highest IED at smallest (most negative) ion energy: 300 V bias grid voltage, 2.5 Å collimating coil currents, and 0.3 Å steering coil currents (optimization figure for the steering coil is not shown).

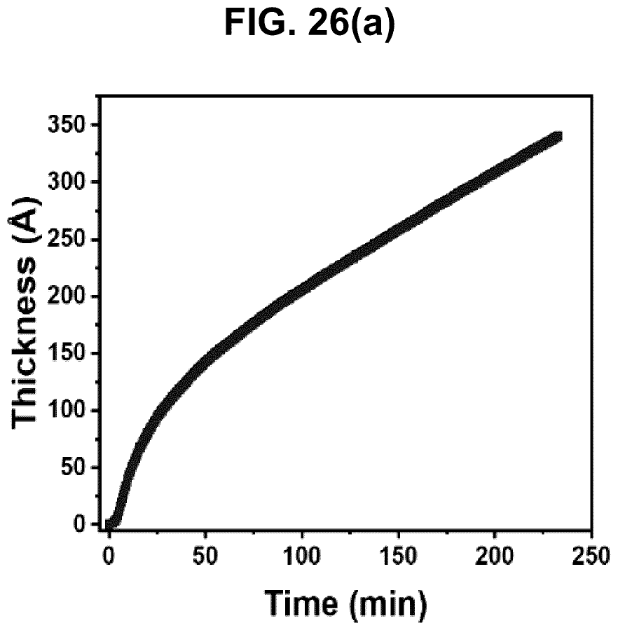

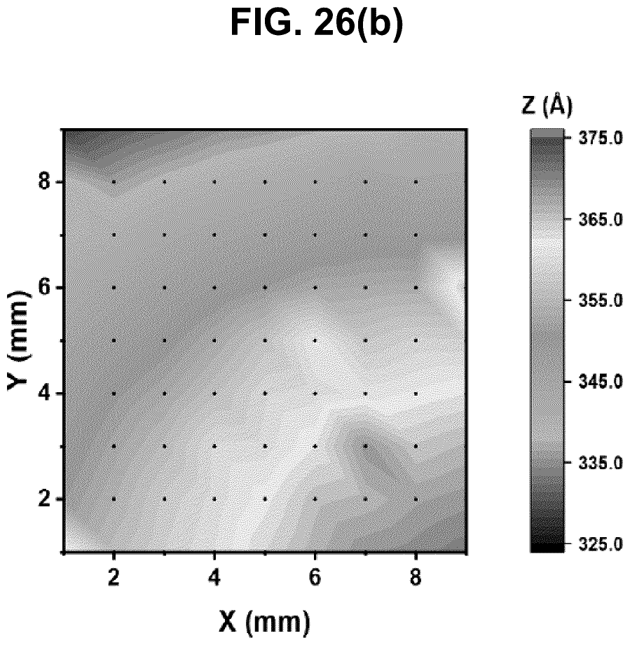

A 400 cycle SiO₂ film was deposited at 35° C. while monitoring with in situ spectroscopic ellipsometry (iSE) (FIG. 26(a)). Each cycle consisted of a 3 s e⁻ dose −3 s purge/1 s Si₂H₆ dose −10 s purge/1 s H₂O dose −10 s purge. 100 sccm N₂ was flowing during the Si₂H₆ doses, the H₂O doses, and all purges. 2.5 sccm Ar was constantly flowing through the hollow cathode. The enhanced growth rate during the initial deposition may be due to better sample conductivity before a thicker dielectric film is deposited. A linear growth rate of 0.58 Å/cycle was obtain after the enhanced growth regime. Film thickness was mapped using ex situ spectroscopic ellipsometry (SE) (FIG. 26(b)). Thickness mapping reveals a high growth region where the electron beam is centered. The electron beam is slightly misaligned relative to the center of the sample. Film density as measured by ex situ X-ray reflectivity (XRR) was 2.32 g/cm3 and index of refraction as measured by ex situ multiangle SE was 1.408+0.00366/λ2. A thermal SiO₂ film was used to compare density and index to the deposited EE-ALD film. The thermal SiO₂ had a density as measured by XRR of 2.34 g/cm3 and an index of 1.469+0.00330/X2 as measured by SE.

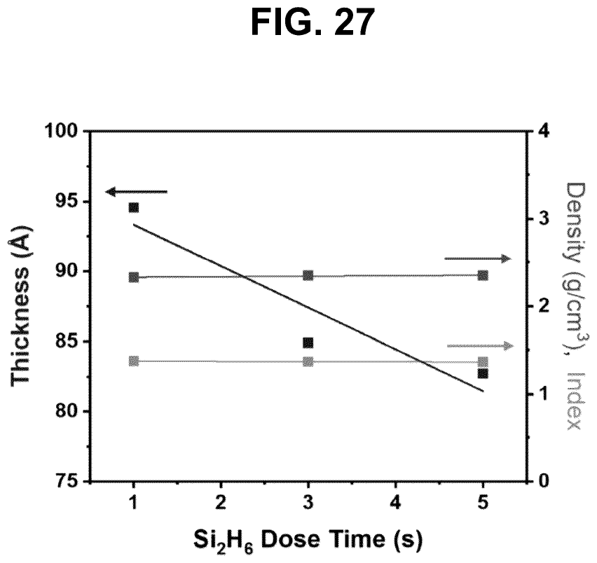

Dependence of the SiO₂ thickness on Si₂H₆ precursor exposure time during SiO₂ EE-ALD is shown in FIG. 27. Three films of 100 EE-ALD cycles each were deposited with either 1 s, 3 s, or 5 s Si₂H₆ exposure times. Each cycle consisted of a 3 s e⁻ dose −5 s purge/X s Si₂H₆ dose −10 s purge/1 s H₂O dose −10 s purge. Film densities and thicknesses were measured with ex situ XRR, and film index was measured with ex situ multiangle SE. Density and index did not show any significant dependence on Si₂H₆ exposure time. Film growth rate slightly decreased for larger Si₂H₆ dose times. This may indicate some competitive adsorption process was occurring during growth.

SiO₂ EE-ALD with Sequential O₃ Process:

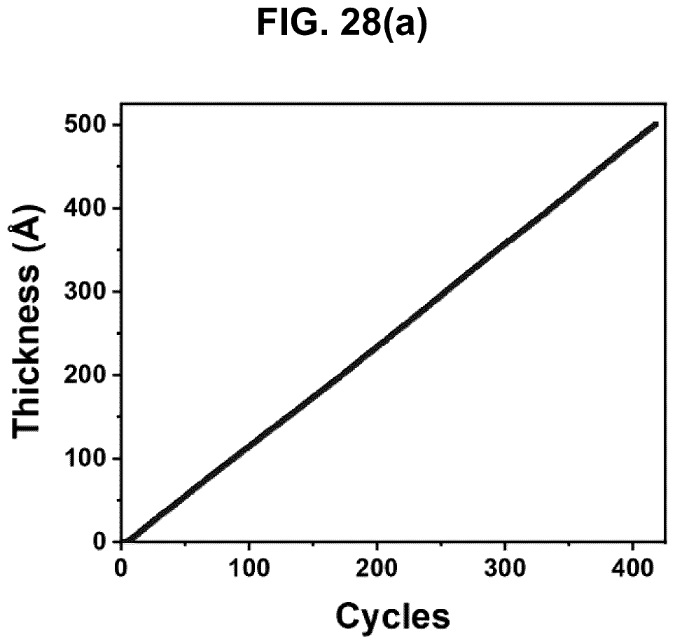

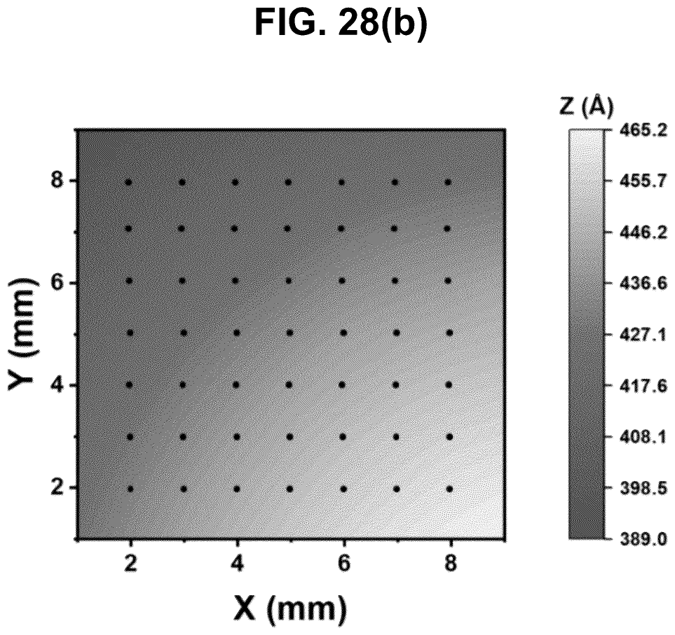

To try and improve SiO₂ film quality, O₃ was used instead of H₂O as the oxygen source. O₃ may allow for reduced hydrogen or —OH groups in the film, which could be one reason for the reduced index measured on SiO₂ films deposited with the H₂O EE-ALD process. FIG. 28(a) shows linear iSE data from 400 EE-ALD cycles at 35° C. Each cycle consisted of a 2 s e⁻ dose −2 s purge/2 s Si₂H₆ dose −10 s purge/1 s O₃ dose −10 s purge. The linear growth rate was 1.21 Å/cycle. Ex situ multiangle SE measured a film index of refraction of 1.651+0.00981/2. This higher index of refraction and lack of an enhanced growth regime, such as seen with the H₂O process, suggests this film may be more conductive and Si rich. Ex situ SE surface mapping is shown in FIG. 28(b). Again, a higher growth region is seen centered around the electron beam.

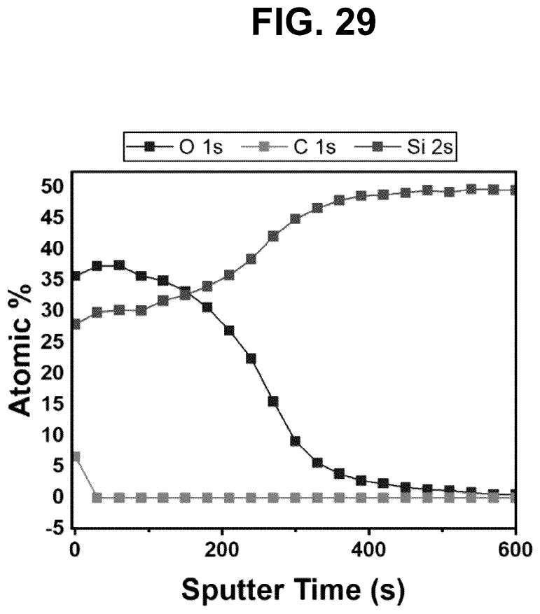

X-ray photoelectron spectroscopy (XPS) depth profiling (FIG. 29) was used to try and estimate the Si:O ratio of the deposited film. The absolute ratio is difficult to determine due to what is thought to be preferential sputtering of oxygen in the films. Even thermal SiO₂ control samples give low Si:O ratios. However, the O₃ EE-ALD film showed an exceptionally low ratio of 1:1.2.

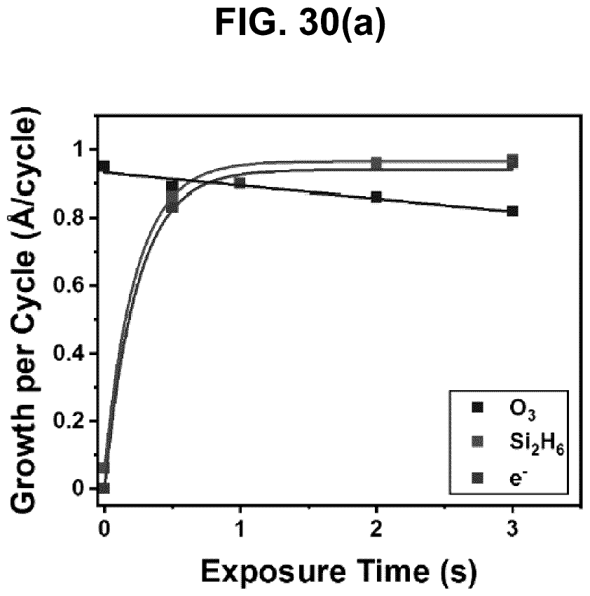

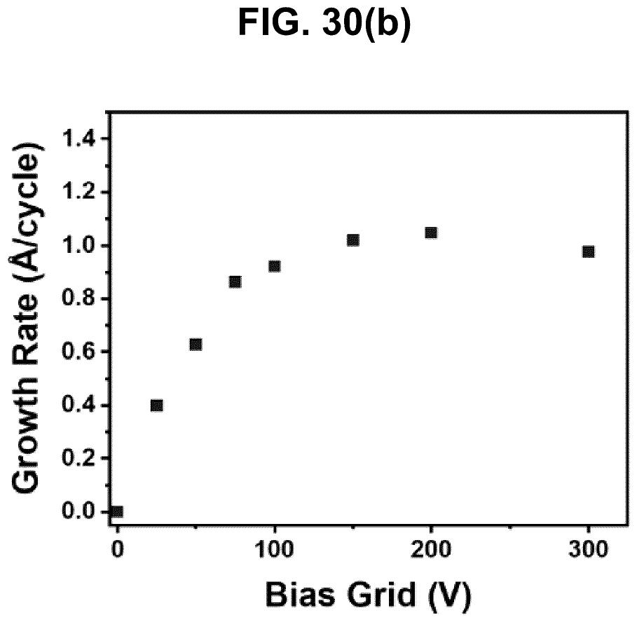

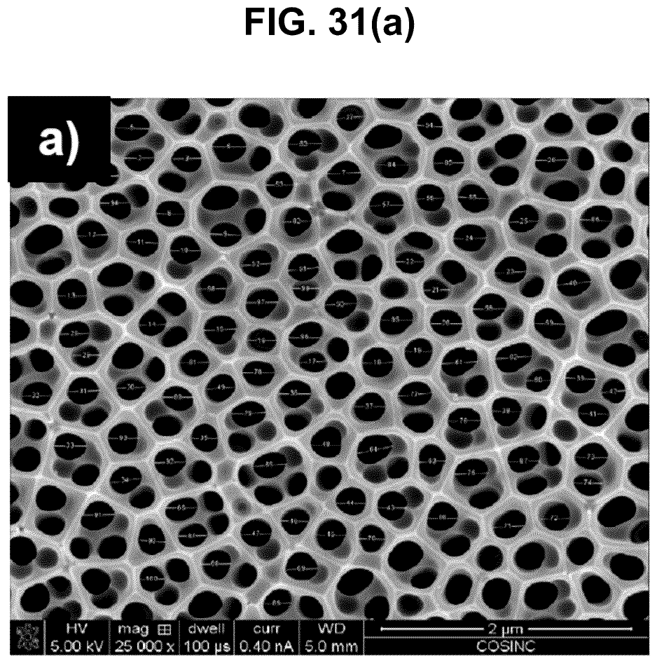

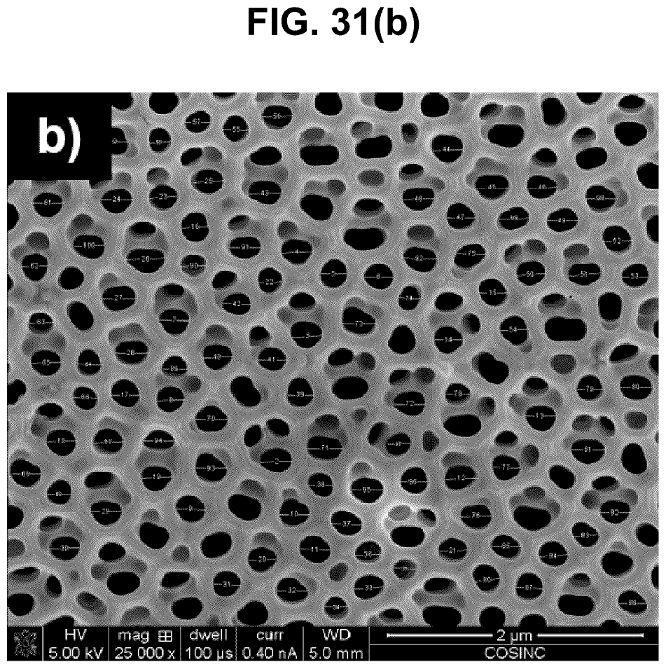

Saturation behavior of the EE-ALD SiO₂ O₃ process can be observed in FIG. 30(a). Each point represents a 25 cycle deposition with either varying the e⁻ exposure time, the Si₂H₆ exposure time, or the O₃ exposure time. Exposure times were varied from 0 to 3 s. Nominal dose parameters when not being varied were 3 s e⁻ doses −3 s purges/1 s Si₂H₆ doses −10 s purges/1 s O₃ doses −10 s purges. Film growth without Si₂H₆ or e⁻ doses were near zero A/cycle, but growth rate quickly saturated at and above 0.5 s. Films could still grow without an O₃ exposure each cycle. This may not be surprising, as SiO₂ films have been grown without an oxygen source exposure each cycle, and films can grow with just background water or oxygen in the chamber. FIG. 30(b) shows the growth rate dependence on the bias grid voltage using cycles of 2 s e⁻ doses −2 s purges/2 s Si₂H₆ doses −10 s purges/1 s O₃ doses −10 s purges.

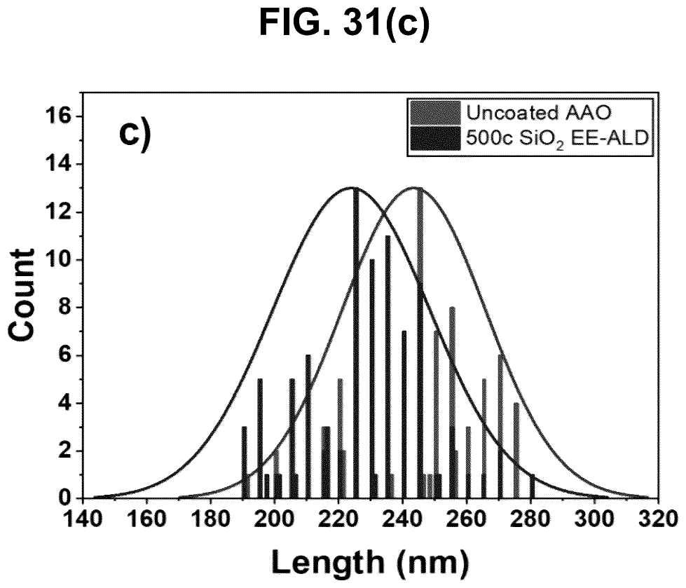

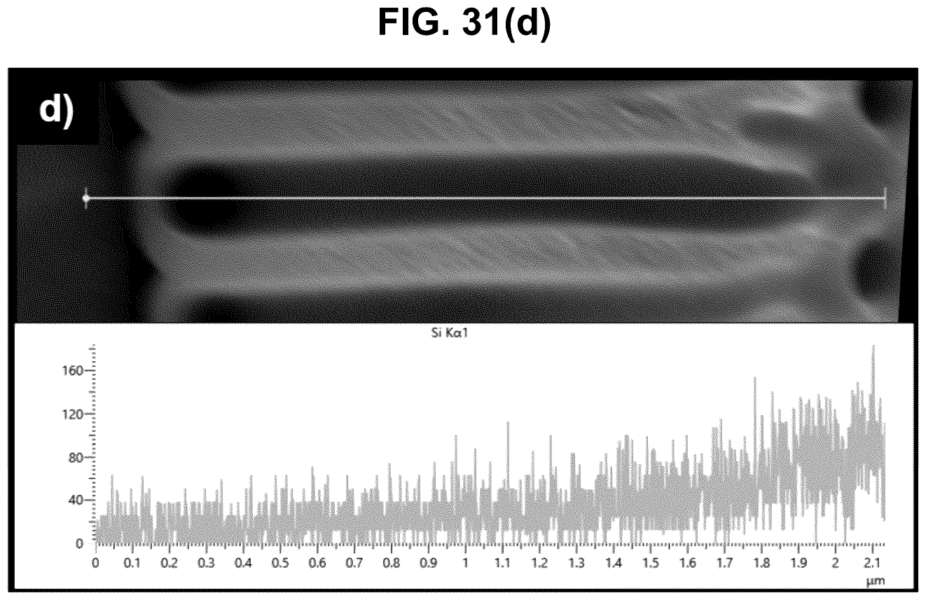

SiO₂ EE-ALD films using the O₃ sequential dose process were deposited onto anodic aluminum oxide (AAO) substrates to assess film conformality and fill capabilities on a vertical high aspect ratio structure. Altered dosing parameters were used to facilitate better pore diffusion. One cycle consisted of a 3 s e⁻ dose −3 s purge/5 s Si₂H₆ dose −15 s purge/2 s O₃ dose −10 s purge. N₂ flow during Si₂H₆ doses, O₃ doses, and all purges was 25 sccm. Dose pressure of the Si₂H₆ was also increased. FIG. 31(a) shows a top down view of the uncoated AAO substrate, and FIG. 31(b) shows a top down view of the AAO substrate after 500 cycles of EE-ALD. Assuming a growth rate of 1.2 Å/cycle, deposited SiO₂ film thickness would be 60 nm. FIG. 31(c) compares pore size distribution between the uncoated and coated AAO substrates. Pore diameters were measured manually using ImageJ software. An energy dispersive X-ray spectroscopy (EDS) line scan for Si on a cross-sectioned pore after EE-ALD is shown in FIG. 31(d). This deposition did not demonstrate bottom-up fill. This may be due to the poor line-of-sight to the bottom of the AAO pores. Si signal is observed in the top portion of the pore.

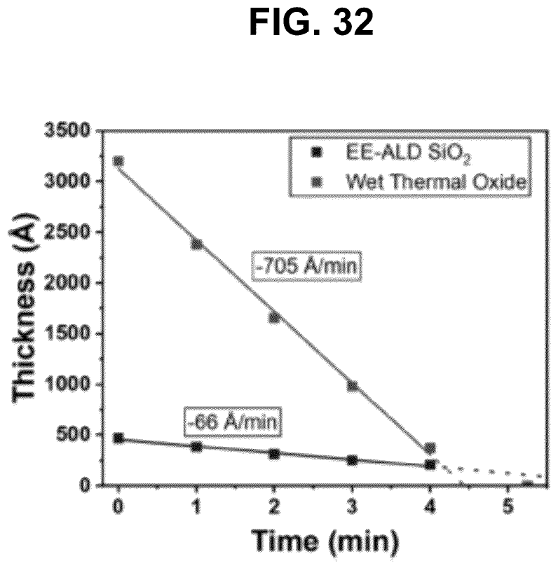

A 6:1 BOE solution (Sigma-Aldrich) was used to compare the etch rate of the EE-ALD SiO₂ film deposited with the O₃ process to the etch rate of a wet thermal SiO₂. Etches were conducted at 20° C. by dipping the sample in the solution for the stated amount of time, with mild swirling, and then rinsing immediately with DI water, followed by an N₂ dry. Samples were then measured with SE and then dipped back into the BOE solution for a given time. Samples were initially cleaned with a sequential acetone, IPA, and DI rinse, followed by an N₂ dry before being etched. FIG. 32 shows the thickness of each film as measured by ex situ SE. The EE-ALD film etches much slower than the wet thermal oxide film, giving further evidence that these films are Si rich.

SiO₂ EE-ALD with Co-Dosing O₃ Process:

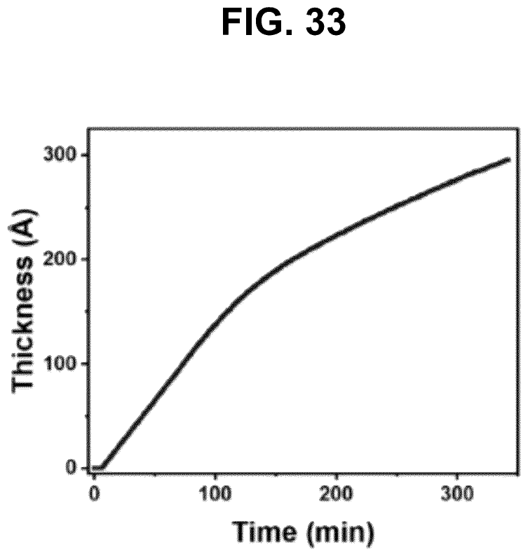

In hopes of improving the Si:O ratio and having SiO₂ EE-ALD films with closer index of refraction and BOE rates to thermal SiO₂, a co-dosing process was used. Cycles consisted of a 5 s O₃|e⁻ co-dose −20 s purge/2 s Si₂H₆ dose −20 s purge. O₃ pressure in the chamber during dosing was <1 mTorr. iSE data from a 400 cycle deposition is shown in FIG. 33. Similar to the H₂O EE-ALD process, this growth shows two different growth regimes. The first linear regime has a growth rate of 1.26 Å/cycle. About halfway through the deposition, the growth slows down and reaches a lower linear growth rate of 0.44 Å/cycle. This lower growth rate may again be due to reduced conductivity of the sample as the dielectric film thickness increases.

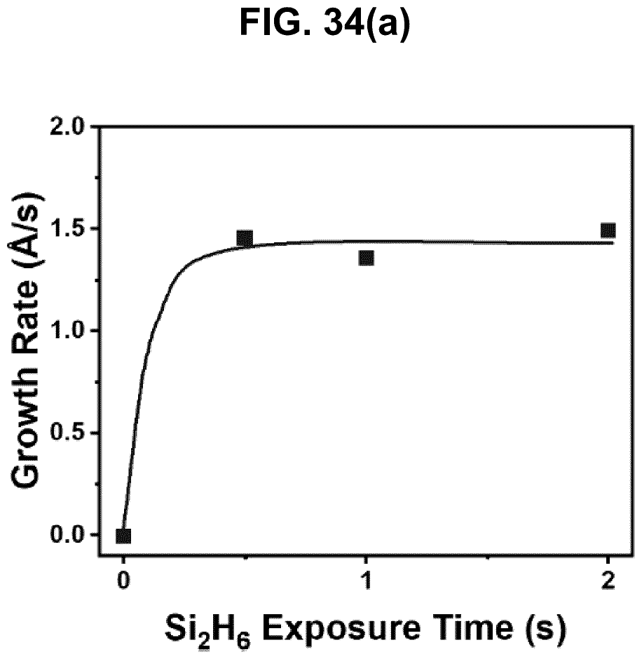

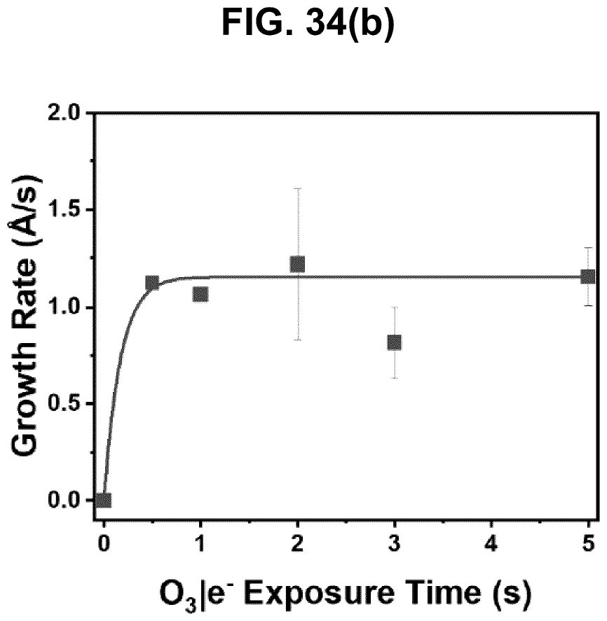

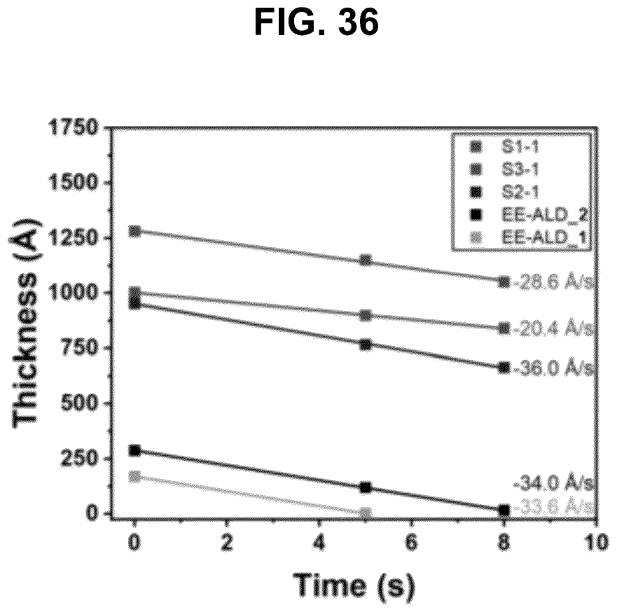

FIG. 34(a) and FIG. 34(b) show saturation growth rate curves verses Si₂H₆ exposure time or O₃|e⁻ co-dose exposure time, respectively, as measured by iSE. Nominal cycle parameters consisted of a 2 s O₃|e⁻ co-dose −20 s purge/2 s Si₂H₆ dose −20 s purge. Each data point represents a 25 cycle deposition. The error bars in FIG. 36(b) are due to inconsistency of the growth rate data, which may be related to the two different growth regimes. These points are averages of two 25 cycle depositions.

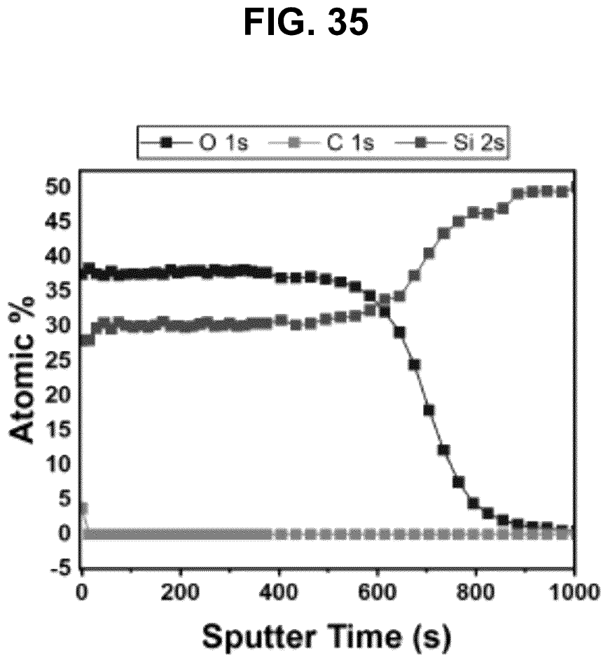

XPS analysis on the previously described 400 cycle SiO₂ EE-ALD O₃|e⁻ co-dose deposition gave an Si:O ratio of 1:1.3. This is still lower than the expected 1:2 for SiO₂ but an improvement over the sequential O₃ process. Again, this low ratio may be due to preferential oxygen sputtering during XPS depth profiling. The XPS data is shown in FIG. 35.

FIG. 36 compares BOE etch rates of two different SiO₂ EE-ALD O₃|e⁻ co-dosing process films with three different SiO₂ samples. EE-ALD_1 used 2 s O₃|e⁻ co-doses, and EE-ALD_2 used 5 s O₃|e⁻ co-doses. Both depositions had 2 s Si₂H₆ doses and 20 s purges. Samples S1-1, S2-1, and S3-1 are the first diced samples from wafers #1, #2, and #3, respectively. Thickness of each film was measured by multiangle ex situ SE. The EE-ALD films etch at a similar rate to the supplied oxides. Film etch rates increase from 53-1<S1-1<EE-ALD_1<EE-ALD_2<52-1. During SE fitting, film index was also measured. Index values can be found in Table 2 below along with density as measured by XRR. Density values do not correlate well with index values. This is attributed to poor fitting in XRR due to the large thickness of the three different SiO₂ sample films and the non-uniformity of the EE-ALD films.

TABLE 2
Index values measured by multiangle ex situ SE and density
values measured by XRR of the films etched in FIG.
36. Index values are of the form n = A + B/λ2.

| | | Density |
|---|---|---|
| Sample ID | Index (A + B) | (g/cm³) |
| S1-1 | 1.448 + 0.00358 | 2.33 |
| S2-1 | 1.451 + 0.00394 | 2.29 |
| S3-1 | 1.458 + 0.00412 | 2.34 |
| EE-ALD_2 | 1.431 + 0.00182 | 2.24 |
| EE-ALD_3 | 1.446 + 0.00202 | 2.36 |

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A method for forming a metal oxide insulating film, comprising conducting electron-enhanced atomic layer deposition with at least one metal-containing precursor gas and at least one oxygen-containing precursor gas as reactants to deposit a metal oxide insulating film on a substrate.

2. The method of claim 1, wherein the metal oxide is selected from the group consisting of SiO₂, TiO₂, HfO₂, and ZrO₂.

3. The method of claim 1, wherein the metal oxide insulating film is a SiO₂ film and the method comprises:
conducting electron-enhanced atomic layer deposition with at least one silicon-containing precursor gas and at least one oxygen-containing precursor gas as reactants to deposit a SiO₂ film on a substrate,
wherein the electron-enhanced atomic layer deposition is conducted at a temperature of less than 300° C.

4. The method of claim 3, wherein the at least one silicon-containing precursor gas comprises Si₂H₆.

5. The method of claim 3, wherein the at least one silicon-containing precursor gas comprises SiH₄.

6. The method of claim 3, wherein the at least one oxygen-containing precursor gas comprises H₂O.

7. The method of claim 3, wherein the at least one oxygen-containing precursor gas comprises O₃.

8. The method of claim 3, wherein the at least one oxygen-containing precursor gas comprises O₂.

9. The method of claim 3, wherein the electron-enhanced atomic layer deposition is conducted with electrons produced by a hollow cathode plasma electron source.

10. The method of claim 3, wherein the electron-enhanced atomic layer deposition is conducted at a temperature of less than 250° C.

11. The method of claim 3, wherein the electron-enhanced atomic layer deposition is conducted at a temperature of less than 200° C.

12. The method of claim 3, wherein the electron-enhanced atomic layer deposition is conducted at a temperature of less than 100° C.

13. The method of claim 3, wherein the electron-enhanced atomic layer deposition is conducted at a temperature of from 15° C. to less than 100° C.

14. The method of claim 3, comprising pulsing electrons sequentially with the at least one silicon-containing precursor gas and the at least one oxygen-containing precursor gas.

15. The method of claim 3, comprising co-dosing electrons with the at least one oxygen-containing precursor gas, followed by sequential dosing of the at least one silicon-containing precursor gas.

16. The method of claim 1, wherein the precursor gases are not subjected to thermal or plasma activation.

17. A metal oxide insulating film produced by the method of claim 1.

18. A SiO₂ film produced by the method of claim 3.

19. The SiO₂ film of claim 18, wherein the SiO₂ film is a blanket film.

20. The SiO₂ film of claim 18, wherein the SiO₂ film is a patterned structure.
